(19) United States
(12) Patent Application Publication
(10) Pub. No.: US 2022/0220132 A1
(43) Pub. Date: Jul. 14, 2022

(54) ORGANOSILANE PRECURSORS FOR ALD/CVD/SOD OF SILICON-CONTAINING FILM APPLICATIONS

(71) Applicant: American Air Liquide, Inc., Fremont, CA (US)

(72) Inventors: Guillaume HUSSON, Newark, DE (US); Claudia FAFARD, Newark, DE (US)

(21) Appl. No.: 17/136,115

(22) Filed: Dec. 29, 2020

(51) Int. Cl. C07F 7/08; C23C 16/455; C23C 16/50; C23C 16/56

(52) U.S. Cl. CPC C07F 7/081; C23C 16/45553; C23C 16/45534; C23C 16/45536; C23C 16/56; C23C 16/50

(57) ABSTRACT

Disclosed are methods of deposition a Si-containing layer that comprise:
exposing a substrate to a vapor of an Si-containing film forming composition comprising an organosilane precursor having the formula

(R′₃Si—CH₂)-(E-(CR)ₙ-E)-(CH₂—SiR′₃)ₓ (I)

R′₃Si—CH₂)—NR₂ (II)

(R′₃Si—CH₂)—NR—SiR′ (III)

wherein
x is 0 or 1;
(E-(CR)ₙ-E) is a monoanionic bidentate ligand bonding to the carbon through one or two Es, wherein
   n is 1 or 3;
   each E is independently chosen from N, NR, O or S; and
   R is independently selected from the group consisting of H, a C₁ to C₆ alkyl group, and a C₃-C₂₀ aryl or heterocycle group; and
each R′ is independently selected from the group of H, a C₁ to C₆ alkyl group, a C₃-C₂₀ aryl, heterocycle group, C₁-C₆ alkoxy group or C₁-C₆ alkylamino; and
depositing at least part of the organosilane precursor onto the substrate to form a Si-containing layer using a deposition method.

### TECHNICAL FIELD

The present invention relates to Si-containing film-forming compositions comprising organosilane precursors, methods of synthesizing the same and methods of using the same to deposit silicon-containing films using ALD, CVD, SOD, etc., in particular to deposit SiN, SiCN, SiO or SiCON film.

### BACKGROUND

Si-containing thin films are used widely in the semiconductor, photovoltaic, LCD-TFT (liquid-crystal display-thin-film transistor), flat panel-type device, refractory material, or aeronautic industries. Si-containing thin films may be used as dielectric materials having electrical properties which may be insulating (e.g., SiO₂, SiN, SiCN, SiCOH, MSiOₓ, wherein M is Hf, Zr, Ti, Nb, Ta, or Ge and x is greater than zero). The Si-containing thin films may also be used as conducting films, such as metal silicides or metal silicon nitrides. Due to the strict requirements imposed by downscaling of electrical device architectures towards the nanoscale (especially below 28 nm node), increasingly fine-tuned molecular precursors are required which meet the requirements of volatility (e.g., atomic layer deposition (ALD) process), lower process temperatures, reactivity with various oxidants and low film contamination, in addition to high deposition rates, conformality and consistency of films produced.

Deposition of silicon carbon nitride (SiCN or SiCₓN_{y}, wherein x and y are each greater than 0) has been widely studied due to their attractive properties, which include low electrical conductivity, high hardness, a low friction coefficient, high photosensitivity in the UV region, and good field emission characteristics. The SiCN layers are also important materials in micro- and nano-electronics, and sensor technologies due to their excellent mechanical and electrical properties. The SiCN films possess good optical transmittance. One of the most important new applications of SiCN films is related to interconnect of advanced nano-electronics devices (King et al., ECS Journal of Solid State Science and Technology, 1(6), N115 (2012)).

The SiCN thin films can be deposited at 400° C. by sputtering a pure silicon target under different argon-methane-nitrogen gas mixture (Appl, Surf. Sci., 444, 2018, 293-302). The SiCN layers deposited by plasma enhanced chemical vapor deposition (PECVD) by using different precursors have been recognized as the most important interlayer diffusion barrier during the last decade. Significant progress has been made in the synthesis of nonstoichiometric SiCN by both physical and chemical methods using different mixtures of simple compounds such as SiH₄, Si₂H₆, Si₃H₈, SiH(CH₃)₃, Si(CH₃)₄, CH₄, NH₃; H₂, C₂H₂, C₃H₈, N₂, etc. can be deposited by ALD using Si₂Cl₆ and CH₃NH₂ plasma. SiCN thin films can also be obtained by chemical vapor deposition (CVD) deposition of SiC and Si₃N₄ nanopowders using N₂ and H₂ mixtures at 1000° C. for several hours. See Hirai et al., J. Mat, Sci., 16, 17 (1981); Bendeddouche et al., J. Appl. Phys., 81, 6147 (1997); Ferreira et al., J. Non-Cryst, Solids; 352, 1361 (2006); Cheng et al., Mat. Chem. Phys., 98, 500 (2006); Chen et al., Diamond Relat. Mat., 14, 1126 (2005); Lin et al., Thin Solid Films; 416, 85 (2002); Hoche et al., Surf. Coat, Tech., 202, 5567 (2008); Mishra et al., Mat. Lett., 62, 398 (2008); 5, K. Mishra, Int. J. Appl. Ceram. Tech., 6, 345 (2009); ECS J. Solid State Sci. Tech., 7(2) N7-N14 (2018); J. Mat, Sci., 53, 1497-1513 (2018); Surf. Rev. Lett., 25, 3; 1850065 (2018), US20180330945A1; Thin Solid Films, 622, 31, Pages 1-10; Chem. Mat., 2017, 29, 15, 6269-6278; J. Alloys and Compounds 789 (2019) 295-302; Bull. Mat. Sci. (2019) 42:251; 2008 International Conference on Advanced Semiconductor Devices and Microsystems, Smolenice, 2008, 291-294; Journal de Physique IV Colloque, 1995, 05 (C5), pp. C5-793-05-800; and Vacuum, 90, 155-159 (2013).

An alternative way of synthesis of SiCN films is through the use of low-toxicity single-source organosilicons precursors containing all the necessary chemical elements, such as Si, 0, and N in one molecule (see Appl. Surf. Sci., 2007, vol. 253, pp. 7211-7218). The SiCN films can be deposited by different CVD methods using cyclosilazane (US2018/0342390), cyclodisilazanes (US2019292658) or silazanes such as silylamines R¹R²NSiH₂—NH—SiH₂—NR³R⁴ (with R¹, R², R³, R⁴ are alkyl or alkenyl) (US 2020/0111665); n-methyl-aza-2,2,4-trimethylsilacyclo-pentane (C₇H₁₇NSi, MTSCP), 1,3-divinyl-1,1,3,3-tetramethyl-disilazane (C₃H₁₉NSi₂, DVTMDS) (Thin Solid Films 636 (2017) 671-679), N-methyl-aza-2,2,4-trimethylsilacyclopentane (MTSCP) (J. Vac, Sci. Tech., B 36, 060601 (2018); and Thin Solid Films, 702, 31, 137983), 1,3-divinyl-1,1,3,3-tetramethyl-disilazane (C₈H₁₉NSi₂, DVTMDS); N-bromohexamethyldisilazane (Inorganic Materials; vol 44, 12; 1312-1318 (2008)), (1,3,5-trimethyl-1,3,5-trivinylcyclotrisilazane (C₉H₂₁N₃Si₃; VSZ), and 1,3,5,7-tetravinyltetra methylcyclotetrasilazane (C₁₂H₂₈N₄Si₄, TVSZ) (Japanese J. Appl. Phys. 58, SHHB01 (2019)); hexamethyldisilazane (HM DS) or hexamethylcyclotrisilazane. See Thin Solid Films, 501, 195 (2006); Thin Solid Films, 516, 652 (2008); Thin Solid Films, 516, 656 (2008); J. Eur. Ceram. Soc., 22, 2969 (2002); Mat, Sci. in Semiconductor Processing 42 (2016) 373-377; Glass Phys. Chem., vol. 35, 274-283 (2009); Glass Phys. Chem., 2019, Vol. 45, No. 6, pp. 525-531; Inorg. Mat., vol. 51, 9, 897-902 (2015); Journal of Physics and Chemistry of Solids Volume 69, Issues 2-3, February-March 2008, Pages 661-668; Journal of structural chemistry, Vol. 56, No. 1, Pp. 163-174, 2015; High Energy Chemistry, vol 49, 273-281 (2015); Russian Journal of General Chemistry, vol 82, 43-52 (2012); Surface & Coatings Technology 201 (2007) 9269-9274.

SiCN thin films can be prepared by using bis(1,1,3,3-tetramethylguanidine)dimethylsilane, tetra(1,1,3,3-tetramethylguanidine)silane and bis(1,1,3,3-tetramethylguanidine)silane as precursors in helicon wave plasma chemical vapor deposition (HWP-CVD) (Appl. Organomet. Chem, 2019; e5349), using bis(dimethylamino) methylsilane in a remote nitrogen plasma chemical vapor deposition (RP-CVD) process (Appl. Organomet. Chem., 31, 12, 2017, e3871), using bis(trimethylsilyl)ethylamine in a mixture with hydrogen by plasma-enhanced CVD (Glass Phys. Chem., vol 38, 1, 8-14 (2012); Glass Phys. Chem., vol 43, 48-52 (2017)) or using methyltris(diethylamino)silane in a plasma chemical vapor deposition (PECVD) process (ECS Journal of solid state science and technology, 4(1) N3153-N3163 (2015)),

US2019/0088474 discloses silyl-substituted hydrazine and silyl-substituted diamine precursor can be deposited by thermal ALD or PEALD to form silicon carbonitride or silicon oxycarbonitride films.

These compounds are of special interest because the molecular structure of the initial organosilicon compound controls the chemical and phase compositions as well as the microstructure of grown nonstoichiometric SiCN films as disclosed by Kroke et. al (Mat. Sci, Eng., 26, 97 (2000)). The pyrolysis of a N-containing polysilazane can be considered as precursor for the manufacturing of silicon carbonitride films. See WO 2011123792; J. Eur. Ceram, Soc., 15, 7, 683-8 (1995); J. Eur, Ceram. Soc., 20, 9, 1365-1374 (2000); J, Am, Ceram. Soc., 76, 5, 1156-62 (1993); Microporous and Mesoporous Mat., 232, 15, 2016, 196-204; Bacher, et al., Applied Surface Science, 5 Mar. 2018, 1-30; and Khatami et al., J Mater Sci, 3 Oct. 2017.

JP 2006096675 to Tsukada et al. discloses disilane containing precursors bearing both alkyl and amino groups for deposition of SiCN thin films.

WO2014015232 and WO2014015237 to Dussarrat et al. disclose silicon amidinate precursors which have the form H₃Si(amd) and silicon β-diketiminate precursors each of which demonstrate the utility of the chelating ligand framework to support the —SiH₃ functionality. WO2014015241 and WO2014015248 to Dussarrat et al. disclose related oxygen containing precursors based upon chelating O—O and N—O delocalized ligand frameworks.

US 2007/0235684 to Mistkawi et al., discloses an etching solution for a metal hard mask, which contains amongst others a dilute HF (hydrofluoric acid) and a silicon containing precursor. The precursor can be an amino functional silane, which includes compound with the structure R₂N—(CH₂)ₙ—Si(OR′)₃, wherein n=1, 2, 3.

EP2586783B1 discloses the method for producing alkoxy hydrosilanes of the formula H—SiR²_{c} (CR^{r}_{3-b}Y_{b})ₐ(OR⁸)_{3-a-c} wherein each R¹ is independently a hydrogen atom or substituted or unsubstituted C₁₋₂₀ hydrocarbon group; each R² is independently a substituted or unsubstituted C₁₋₂₀ hydrocarbon group: Y is selected from a halogen atom, —OR³, NR⁴R⁵, N═R⁶, SR⁷ (wherein R³, R⁴, R⁵ and R⁷ are each a hydrogen atom or C₁₋₂₀ substituted or unsubstituted hydrocarbon group, and R⁶ is a divalent C₁₋₂₀ substituted or unsubstituted hydrocarbon group), a C₁₋₂₀ perfluoroalkyl group, and a cyano group; R⁸ is a substituted or unsubstituted C₁₋₂₀ hydrocarbon group; a is 1 or 2, b is 1, 2 or 3, and c is 1 or 0 provided that a+c is not more than 2.

U.S. Pat. No. 8,426,319 to Mistkawi et al. discloses phenylaminomethyltrimethoxysilane, phenylaminomethyltriethoxysilane and diethylaminomethyltriethoxysilane as amino functional silanes for a composition for etching a metal hard mask material in semiconductor processing.

US2007/0100111 discloses alkoxysilanes having the formula B¹CH₂SiR¹ₐ(OR²)₃₋ₐ, wherein B¹ is an OH, SH or NH₂ group or a group HR⁴N; R² is an optionally halogen-substituted cyclic, linear or branched C₁ to C₁₈ alkyl radical or alkenyl radical or a C₆ to C₁₈ aryl radical, as a component in the preparation of alkoxysilane terminated prepolymers. The preparation of methoxymethyltrimethoxysilane (MeOCH₂Si(OMe)₃) is disclosed.

Exemplary references also include SU395370A1, CN1027754338, CN1028977658, CN1028984608, CN1033332008, CN104086583A, and CN104086584A.

Despite the wide range of choices available for the deposition of Si containing films, additional precursors are continuously sought to provide device engineers the ability to tune manufacturing process requirements and achieve films with desirable electrical and physical properties.

### SUMMARY

Disclosed is a Si-containing film forming composition comprising an organosilane precursor, the organosilane precursor having the following formula:

(R′₃Si—CH₂)-(E-(CR)ₙ-E)-(CH₂—SiR′₃)ₓ (I)

R′₃Si—CH₂)—NR₂ (II)

(R′₃Si—CH₂)—NR—SiR′ (III)

wherein

x is 0 or 1;

(E-(CR)ₙ-E) is a monoanionic bidentate ligand bonding to the carbon through one or two Es, wherein

n is 1 or 3;

each E is independently chosen from N, NR, O or S; and

R is independently selected from the group consisting of H, a C₁ to C₆ alkyl group, and a C₃-C₂₀ aryl or heterocycle group; and

each R′ is independently selected from the group of H, a C₁ to C₆ alkyl group, a C₃-C₂₀ aryl, heterocycle group, C₁-C₆ alkoxy group or C₁-C₆ alkylamino. The disclosed Si-containing film forming composition may include one or more of the following aspects:
the organosilane precursor being (R′₃Si—CH₂)—(NR¹—(CR²)—NR³), wherein R¹, R², R³ may each independently be H, a C₁ to C₆ alkyl group, or a C₃-C₂₀ aryl or heterocycle group; R¹ and R² and/or R² and R³ may be joined to form cyclic chains; R′ is independently selected from the group of H, a C₁ to C₆ alkyl group, a C₃-C₂₀ aryl, heterocycle group, C₁-C₆, alkoxy group or C₁-C₆ alkylamino;
the organosilane precursor being (R′₃Si—CH₂)—(NR¹—(CR²)—NR³), wherein R¹, R², R³ may each independently be H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being R′₃Si—CH₂(R¹N—(CR²)—O), wherein R¹, R², may each independently be H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆, alkoxy group or C₁-C₆ alkylamino;
the organosilane precursor being R′₃Si—CH₂(R²N—(CR¹)═S), wherein R¹, R² each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(O—(CR)═O), wherein R is H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(O—(CR)═S), wherein R is H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(S—(CR)═S), wherein R is H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(R¹N—(CR²)—(CR³)—(CR⁴)—NR′, wherein R¹, R², R³, R⁴ and R⁵ each is independently H, a C₁ to C₆ alkyl group, or a C₃-C₂₀ aryl or heterocycle group; R¹ and R² and/or R² and R³ and/or R³ and R⁴ and/or R⁴ and R⁵ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(R¹N—(CR²)—(CR³)—(CR⁴)—NR⁵, wherein R¹, R², R³, R⁴ and R⁵ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(R¹N—(CR²)—(CR³)—(CR⁴)═O), wherein R¹, R², R³ and R⁴ each is independently H, a C₁ to C₆ alkyl group, or a C₃-C₂₀ aryl or heterocycle group; R¹ and R² and/or R² and R³ and/or R³ and R⁴ may be joined to form cyclic chains; R′ is independently selected from the group of H, a C₁ to C₆ alkyl group, a C₃-C₂₀ aryl, heterocycle group, C alkoxy group or C₁-C₆ alkylamino;
the organosilane precursor being SiR′₃—CH₂(R¹N—(CR²)—(CR³)—(CR⁴)═O), wherein R¹, R², R³ and R⁴ each is independently H, a C₁ to C₆ alkyl group, or a C₃-C₂₀ aryl or heterocycle group; R′ is independently selected from the group of H, a C₁ to C₆ alkyl group, a C₃-C₀ aryl, heterocycle group, C₁-C₆ alkoxy group or C₁-C₆ alkylamino;
the organosilane precursor being SiR′₃—CH₂(R¹N—(CR²)—(CR³)—(CR⁴)═S), wherein R¹, R², R³ and R⁴ each is independently H, a C₁ to C₆ alkyl group, or a C₃-C₂₀ aryl or heterocycle group; R¹ and R² and/or R² and R³ and/or R³ and R⁴ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(R¹N—(CR²)—(CR³)—(CR⁴)═S), wherein R¹, R², R³ and R⁴ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(O—(CR¹)—(CR²)—(CR³)═O), wherein R¹, R² and R³ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(O—(CR¹)—(CR²)—(CR³)═O), wherein R¹, R² and R³ each is independently H, a C₁ to C₆ alkyl group, or a C₃-C₂₀ aryl or heterocycle group; R¹ and R² and/or R² and R³ may be joined to form cyclic chains; R′ is independently selected from the group of H, a C₁ to Cc alkyl group, a C₃-C₂₀ aryl, heterocycle group, C₁-C₆ alkoxy group or C₁-C₆ alkylamino;
the organosilane precursor being SiR′₃—CH₂(O—(CR′)—(CR²)—(CR³)═S), wherein R¹, R² and R³ each is independently H, a C₁ to C₆ alkyl group, or a C₃-C₂₀ aryl or heterocycle group; R′ is independently selected from the group of H, a C₁ to C₆ alkyl group; a C₃-C₂₀ aryl, heterocycle group, C₁-C₆ alkoxy group or C₁-C₆ alkylamino;
the organosilane precursor being SiR′₃—CH₂(O—(CR¹)—(CR²)—(CR³)═S), wherein R¹, R² and R³ each is independently H, a C₁ to C₆ alkyl group, or a C₃-C₂₀ aryl or heterocycle group; R¹ and R² and/or R² and R³ may be joined to form cyclic chains; R′ is independently selected from the group of H, a C₁ to Cc alkyl group, a C₃-C₂₀ aryl, heterocycle group, C₁-C₆ alkoxy group or C₁-C₆ alkylamino;
the organosilane precursor being SiR′₃—CH₂(S—(CR¹)—(CR²)—(CR³)═S), wherein R¹, R² and R³ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being SiR′₃—CH₂(S—(CR¹)—(CR²)—(CR³)═S), wherein R¹, R² and R³ each is independently H, a C₁ to C₆ alkyl group, or a C₃-C₂₀ aryl or heterocycle group; R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(R¹N—(CR²)—N), wherein R¹ and R² each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(RN—(CR)—O), wherein R is H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(RN—(CR)═S), wherein R is H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(R¹N—(CR²)—(CR³)—(CR⁴)—N), wherein R¹, R², R³ and R⁴ each is independently H, a C₁ to C₆ alkyl group, or a C₃-C₂₀ aryl or heterocycle group; R¹ and R² and/or R² and R³ and/or R³ and R⁴ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(R¹N—(CR²)—(CR³)—(CR⁴)—N), wherein R¹, R², R³ and R⁴ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(N—(OR¹)—(OR²)—(CR³)═O), wherein R¹, R², R³ may each independently be H, a C₁ to C₆ alkyl group, or a C₃-C₂₀ aryl or heterocycle group; R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₂)₂(R¹N—(OR²)—(CR³)—(CR⁴)—N), wherein R¹, R², R³ and R⁴ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C alkoxy group or C₁-C₆ alkylamino;
the organosilane precursor being (SiR′₃—CH₂)₂(N—(CR′)—(CR²)—(OR³)═S), wherein R¹, R², R³ may each independently be H, a C₁ to C₆ alkyl group, or a C₃-C₂₀ aryl or heterocycle group; R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino;
the organosilane precursor being (SiR′₃—CH₃)₂(N—(CRI)—(CR²)—(OR³)═S), wherein R¹, R², R³ may each independently be H, a C₁ to C₆ alkyl group, or a C₃-C₂₀ aryl or heterocycle group; R′ is independently selected from the group of H, a C₁ to C₆ alkyl group, a C₃-C₂₀ aryl; heterocycle group; C₁-C₆ alkoxy group or C₁-C₆ alkylamino;
the organosilane precursor being

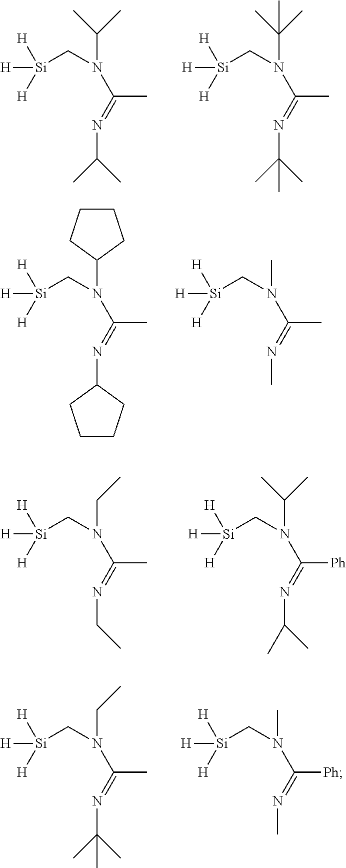

the organosilane precursor being

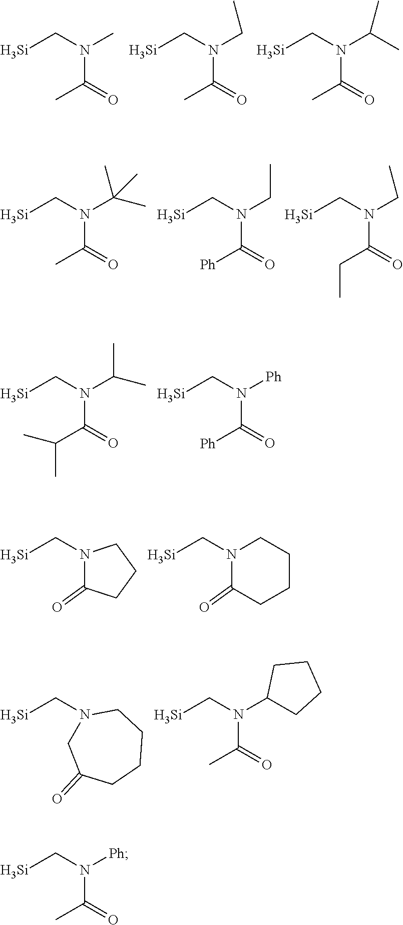

the organosilane precursor being

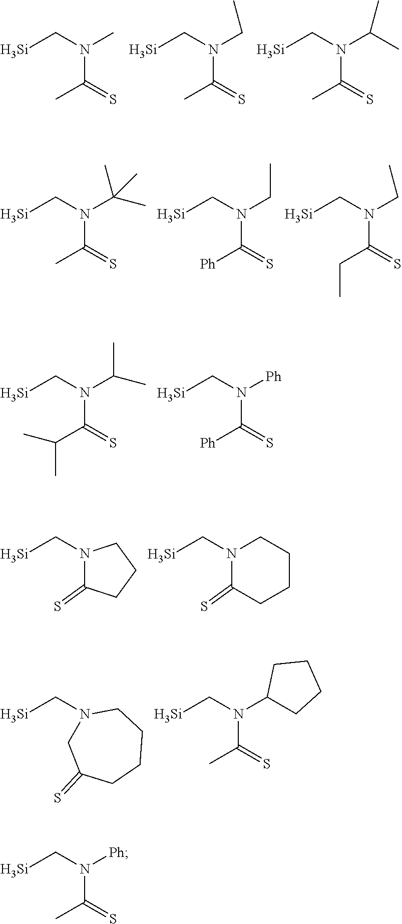

the organosilane precursor being

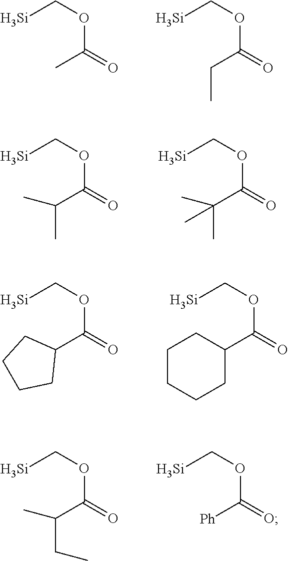

the organosilane precursor being

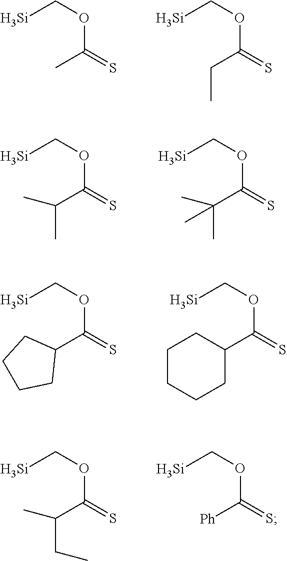

the organosilane precursor being

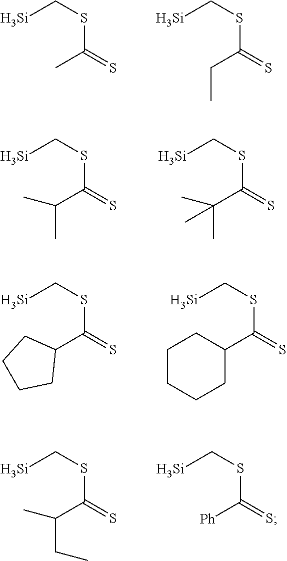

the organosilane precursor being

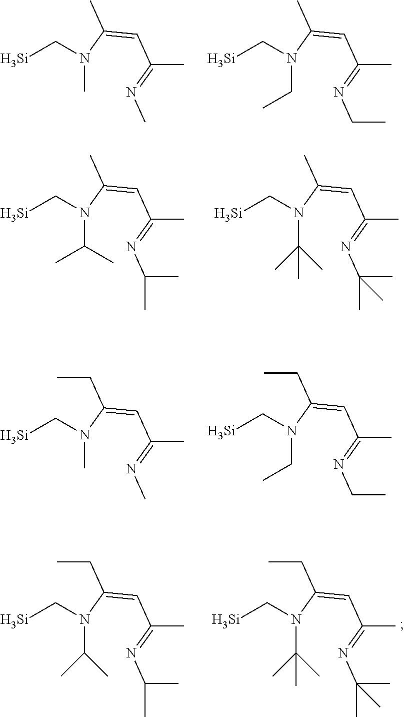

the organosilane precursor being

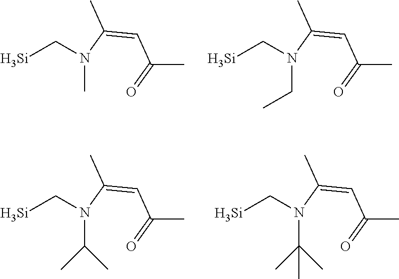

the organosilane precursor being

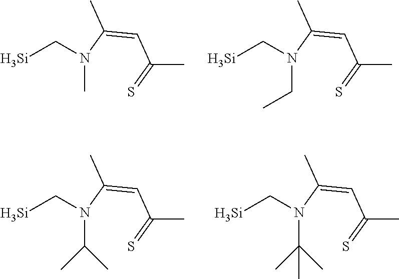

the organosilane precursor being

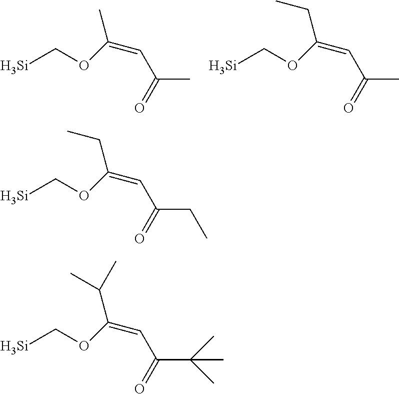

the organosilane precursor being

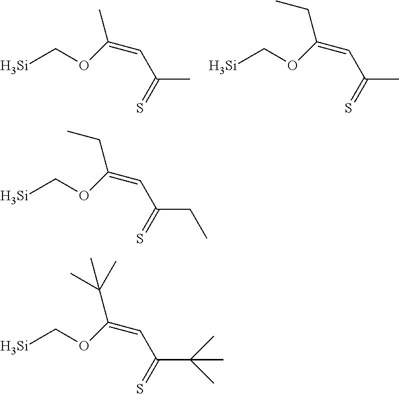

the organosilane precursor being

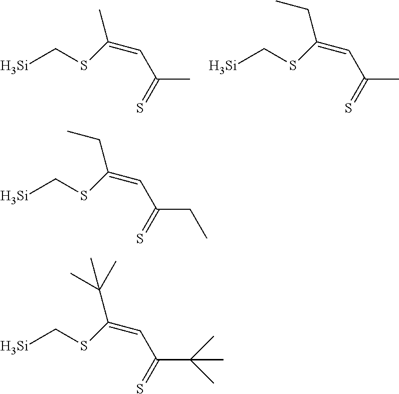

the organosilane precursor being

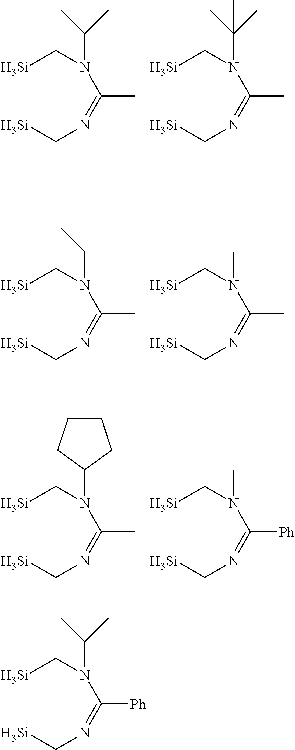

the organosilane precursor being

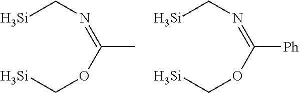

the organosilane precursor being

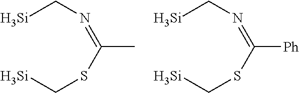

the organosilane precursor being

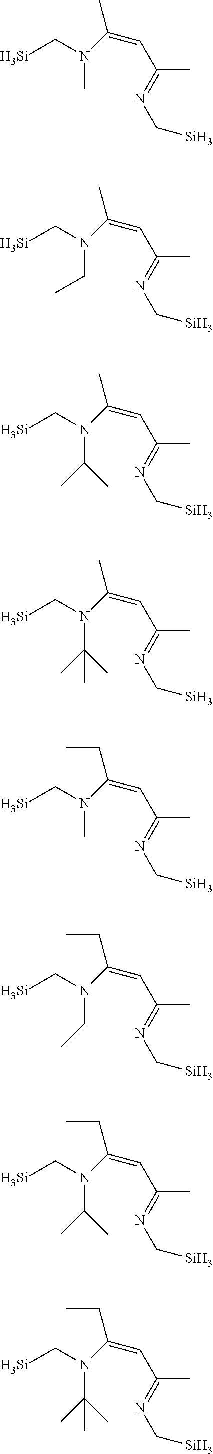

the organosilane precursor being

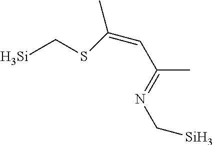

the organosilane precursor having a purity ranging from approximately 90% w/w to approximately 100% w/w; and
the organosilane precursor having a purity ranging from approximately 99% w/w to approximately 99.999% w/w.

Disclosed is a method of deposition a Si-containing layer on a substrate, the method comprising:

exposing a substrate to a vapor of an Si-containing film forming composition comprising an organosilane precursor having the formula

(R′₃Si—CH₂)-(E-(CR)ₙ-E)-(CH₂—SiR′₃)ₓ (I)

R′₃Si—CH₂)—NR₂ (II)

(R′₃Si—CH₂)—NR—SiR′ (III)

wherein

x is 0 or 1;

(E-(CR)ₙ-E) is a monoanionic bidentate ligand bonding to the carbon through one or two Es, wherein
n is 1 or 3;
each E is independently chosen from N, NR, O or S; and
R is independently selected from the group consisting of H, a C₁ to C₆ alkyl group, and a C₃-C₂₀ aryl or heterocycle group; and

each R′ is independently selected from the group of H, a C₁ to C₆ alkyl group, a C₃-C₂₀ aryl, heterocycle group, C₁-C₆ alkoxy group or C₁-C₆ alkylamino; and

depositing at least part of the organosilane precursor onto the substrate to form a Si-containing layer using a deposition method. The disclosed Si-containing film forming composition may include one or more of the following aspects;
the deposition method being an ALD or CVD;
the deposition method being an ALD;
the deposition method being a CVD;
the deposition method being a SOD;
the deposition method being a PEALD;
the deposition method being a spatial ALD;
further comprising the step of adding a co-reactant to the Si-containing film forming composition;
the co-reactant being selected from the group consisting of O₂, O₃, H₂O, H₂O₂, NO, NO₂, N₂O, a carboxylic acid, plasma treated oxygen, radicals thereof, and combinations thereof;
the co-reactant being an oxidizing agent such as one of O₂; O₃; H₂O; H₂O₂, N₂O₂; NO, NO₂, oxygen containing radicals such as [symbol] or O [symbol] ; NO; NO₂; carboxylic acids such as formic acid, acetic acid, propionic acid; radical species of NO, NO₂, or the carboxylic acids; para-formaldehyde; and mixtures thereof;
the co-reactant being O₂ or O₃;
the co-reactant being O₂;
the co-reactant being O₃;
the co-reactant being selected from the group consisting of H₂, NH₃, (SiH₃)₃N, hydridosilanes (such as SiH₄, Si₂H₆, Si₃H₃, Si₄H₁₀, Si₅H₁₀, Si₆H₁₂), halosilanes, including chlorosilanes and chloropolysilanes (such as SiHCl₃, SiH₂Cl₂, SiH₃Cl, Si₂Cl₆, Si₂HCl₅, Si₃Cl₈, Si₂H₂Cl₄, and cyclo-Si₆H₆Cl₆), alkysilanes (such as Me₂SiH₂, Et₂SiH₂, MeSiH₃, EtSiH₃), hydrazines (such as N₂H₄, MeeHNNH₂, MeHNNHMe), organic amines (such as NMeH₂, NEtH₂, NMe₂H, NEt₂H, NMe₃, NEt₃, (SiMe₃)₂NH), pyrazoline, pyridine, B-containing molecules (such as B₂H₆, 9-borabicylo[3,3,1]none, trimethylboron, triethylboron, borazine), alkyl metals (such as trimethylaluminum, triethylaluminum, dimethylzinc, diethylzinc), radical species thereof, and mixtures thereof;
the co-reactant being NH₃;
the Si-containing layer being a SiN layer;
the Si-containing layer being a SiCN layer;
the Si-containing layer being a SiCON layer;
the Si-containing layer being a SiN, SiCN, SiO or SiCON layer;
further comprising adding a second precursor to the the Si-containing film forming composition;
an element of the second precursor being selected from the group consisting of group 2, group 13, group 14, transition metals, lanthanides, and combinations thereof; and
further comprising the step of annealing the Si-containing layer through thermal annealing, furnace-annealing, rapid thermal annealing, UV or e-beam curing, and/or plasma gas exposure.

### Notation and Nomenclature

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “ambient temperature” refers to an environment temperature approximately 20° C. to approximately 25° C.

The term “substrate” refers to a material or materials on which a process is conducted. The substrate may refer to a wafer having a material or materials on which a process is conducted. The substrates may be any suitable wafer used in semiconductor, photovoltaic, flat panel; or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM (metal-insulator-metal), DRAM (dynamic random-access memory), or FeRam (ferroelectric random-access memory) device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. The substrate can be any solid that has functional groups on its surface that are prone to react with the reactive head of a SAM, and may include without limitation 3D objects or powders.

Note that herein, the terms “film” and “layer” may be used interchangeably. It is understood that a film may correspond to, or related to a layer, and that the layer may refer to the film. Furthermore, one of ordinary skill in the art Will recognize that the terms “film” or “layer” used herein refer to a thickness of some material laid on or spread over a surface and that the surface may range from as large as the entire wafer to as small as a trench or a line.

The terms “via”, “aperture” and “hole” are sometimes used interchangeably, and generally mean an opening in an interlayer insulator.

As used herein, the abbreviation “NAND” refers to a “Negated AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

The term “wafer” or “patterned wafer” refers to a wafer having a stack of silicon-containing films on a substrate and a patterned hardmask layer on the stack of silicon-containing films formed for pattern etch. The term “wafer” or “patterned wafer” may also refers to a trench wafer having an aspect ratio.

Note that herein, the terms “deposition temperature” and “substrate temperature” may be used interchangeably. It is understood that a substrate temperature may correspond to, or related to a deposition temperature, and that the deposition temperature may refer to the substrate temperature.

Note that herein, the terms “precursor” and “deposition compound” and “deposition gas” may be used interchangeably when the precursor is in a gaseous state at room temperature and ambient pressure. It is understood that a precursor may correspond to, or related to a deposition compound or deposition gas, and that the deposition compound or deposition gas may refer to the precursor.

As used in the disclosed embodiments, the term “hydrocarbyl group” refers to a functional group containing carbon and hydrogen; the term “alkyl group” refers to saturated functional groups containing exclusively carbon and hydrogen atoms. The hydrocarbyl group may be saturated or unsaturated. Either term refers to linear, branched, or cyclic groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “heterocycle” refers to cyclic compounds that have atoms of at least two different elements as members of its ring.

As used herein, the term “hetero group” refers to a functional group containing C and a second non-H element, such as S or 0.

As used herein, the term “amd” or “AMD” refers to amidinate ligand, i.e., —R¹N(CR³)═NR², where R¹, R², R³=H, alkyl, cycloalkyl.

The standard abbreviations of the elements from the periodic table of elements are used herein. It should be understood that elements may be referred to by these abbreviations (e.g., Si refers to silicon, N refers to nitrogen, 0 refers to oxygen, C refers to carbon, etc.).

As used in the disclosed embodiments, the abbreviation “Me” refers to a methyl group; the abbreviation “Et” refers to an ethyl group; the abbreviation “Pr” refers to a propyl group.

The unique CAS registry numbers (i.e., “CAS”) assigned by the Chemical Abstract Service are provided to identify the specific molecules disclosed.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

Please note that the films or layers deposited, such as silicon oxide or silicon nitride, may be listed throughout the specification and claims without reference to their proper stoichiometry (i.e., SiO₂, Si₃N₄). The layers may include pure (Si) layers, carbide (SiC) layers, nitride (SiN) layers, oxide (SiO), carbonitride (SiCN) and carbooxynitride (SiCON) layers, or mixtures thereof. More preferably, the silicon oxide layer is SiO₂. The silicon oxide layer may be a silicon oxide based dielectric material, such as organic based or silicon oxide based low-k dielectric materials such as the Black Diamond II or Ill material by Applied Materials, Inc.. Alternatively, any referenced silicon-containing layer may be pure silicon. Any silicon-containing layers may also include dopants, such as B, C, P, As and/or Ge.

Ranges may be expressed herein as from about one particular value, and/or to about another particular value. Mien such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a graph of precursor series of Growth Per Cycle (GPO) and Wet Etch Rate (WER) when the precursor purge was 5 seconds;

FIG. 2 is a graph of precursor pulse series of Growth Per Cycle (GPC) and Wet Etch Rate (WER) when the precursor purge is increased from 5 seconds to 20 seconds;

FIG. 3 is the compositional analysis of SiN(C) deposited by SiH₃—CH₂—N(iBu)₂ with N₂ for the precursor purge series; and

FIG. 4 is STIR (Fourier-transform infrared spectroscopy) spectrum after a plasma power series.

### DESCRIPTION OF PREFERRED EMBODIMENTS

Disclosed are Si-containing film-forming compositions comprising organosilane precursors, methods of synthesizing the same and methods of using the same to deposit silicon-containing films using ALD, CVD, SOD, etc., for manufacturing semiconductors, photovoltaics, LCD-TFT, flat panel-type devices, refractory materials, or aeronautics. In particular, the disclosed relates to ALD processes for deposition of SiN, SiCN, SiO or SiCON films.

The disclosed organosilane precursors have the following formula

(R′₃Si—CH₂)-(E-(CR)ₙ-E)-(CH₂—SiR′₃)ₓ (I)

R′₃Si—CH₂)—NR₂ (II)

(R′₃Si—CH₂)—NR—SiR′ (III)

wherein

x is 0 or 1;

(E-(CR)ₙ-E) is a monoanionic bidentate ligand bonding to the carbon through one or two Es, wherein
n is 1 or 3;
each E is independently chosen from N, NR, 0 or S; and
R is independently selected from the group consisting of H, a C₁ to C₆ alkyl group, and a C₃-C₂₀ aryl or heterocycle group; and

each R′ is independently selected from the group of H, a C₁ to C₆ alkyl group, a C₃-C₂₀ aryl, heterocycle group, C₁-C₆ alkoxy group or C₁-C₆ alkylamino.

In the formula (I), the E atoms are bonded to the silicon atom, resulting in a tetracoordinate or pentacoordinate Si(IV) center. The carbon atom in the backbone of the bidentate monoanionic ligand is sp² hybridized, resulting in a delocalized charge across the ligand. The carbon atoms may independently be substituted by H, C₁-C₆ alkyl groups, aryl groups, or heterocycle groups.

Preferably, the disclosed Si-containing film forming compositions have suitable properties for vapor depositions and spin on depositions, such as high vapor pressure, low melting point (preferably being in liquid form at room temperature), low sublimation point, and high thermal stability. More specifically, the disclosed Si-containing film forming compositions may show high thermal stability upon heating over time. The bulkier R groups on silicon may help stabilize the disclosed Si-containing film forming compositions.

The Si-containing film forming compositions may be suitable for the deposition of Si-containing films, such as, Si, SiO₂, SiON, SiCOH, SiCN, SiCON, SiN, MSiOₓ (here M may be an element such as Hf, Zr, Ti, V, Nb, Ta, or Ge, and x may be 0-4 depending upon the oxidation state of M), preferably SiCN or SiCON, films by various ALD or CVD processes, such as, ALD, PEALD, PVD, CVD, PECVD, flowable ALD/CVD, dual silicone source deposition (DSSD), selective ALD, and spin-on deposition, and may have the following advantages:
liquid at room temperature or having a melting point lower than 100° C.;
thermally stable to enable proper distribution (gas phase or direct liquid injection) without particles generation;
suitable reactivity with the substrate to permit a wide self-limited ALD window, allowing deposition of a variety of Si-, Ge- and Sn-containing films, including ternary or quaternary materials, by using one or a combination of reactants selected from the group comprising of H₂, NH₃, O₂, H₂O, O₃, SiH₄, Si₂H₆, Si₃H₆, SiH(NMe₂)₃ (tris(dimethylamino)silane, TriDMAS or TDMAS), SiH₂(NMe₂)₂ (bis(dimethylamino)silane, BDMAS), SiH₂(N(Et)₂)₂ (bis(diethylamino)silane, BDEAS), Si H(N(Et)₂)₃(tris(diethylamino)silane, TDEAS), SiH(NEtMe)₃ (tris(ethylmethylamino)silane, TERAS), (SiH₃)₃N, (SiH₃)₂O, an aluminum-containing precursor such as trimethyl aluminum (TMA), Ta(=NtBu)(NEt₂)₃ ((tert-butylimido)tris(diethylamido) tantalum, TBTDET), Ta(OEt)₄(OCH₂CH₂NIVIe₂) (tantalum tetraethoxide dimethylaminoethoxide, TAT-DMAE), polyethylene terephthalate (PET), Nb(=NtBu)(NMe₂)₂ ((tert-butylimido)bis(dimethylamino) niobium, TBTDEN), polyethylene naphthalate (PEN), lanthanide-containing precursors such as Ln(tmhd)₃ (lanthanide (2,2,6,6-tetramethyl-3,5-heptanedione)₃).

When x=0, n=1, and E is NR containing amidinate functionality in the formula (I), exemplary organosilane precursors include mono(amidinato)carbosilanes (R′₃Si—CH₂)—(NR¹—(CR²)—NR³) and have the following structural formula:

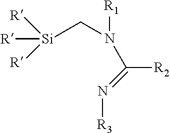

wherein R¹, R² and R³ may each independently be H, a C₁ to C₆ alkyl group, or a C₃-C₂₀ aryl or heterocycle group; R¹ and R² and/or R¹ and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(Amidinato)Carbosilanes Include:

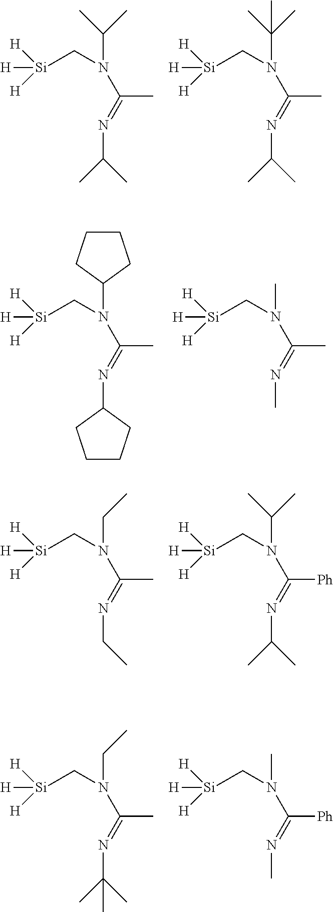

The disclosed (R′₃Si—CH₂)—(NR¹—(CR²)—NR³) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN(CR)NR] under atmosphere of nitrogen, the outlet of the mixing flask being connected to an oil bubbler to inhibit backflow of air and moisture. Another synthetic route to the disclosed (R″₃Si—CH₂)—(NR¹—(CR²)—NR³) precursors is to combine a hydrocarbon solution of XCH₂SiR′₃, wherein X is Cl, Br, I, or triflate (SO₃CF₃), with a neat or hydrocarbon solution of the protonated ligand (HRN(CR)NR) under an inert atmosphere. Alternatively, the disclosed (R′₃Si—CH₂)—(NR¹—(CR²)—NR³) precursors may be synthesized by reaction of XCH₂—SiX₃, wherein X is Cl, Br, I, or triflate (SO₃CF₃), with one equivalent of the ligand compound Li[RN(CR)NR] or two equivalents of the ligand compound H[RN(CR)NR]. Then a filtration of the products is followed. Afterward, a subsequent reduction is performed using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN(CR)NR] all of the starting materials are commercially available. The ligand compound Li[RN(CR)NR] may be synthesized by combining a hydrocarbon solution of metalorganic salt (i.e., alkyl lithium) to a hydrocarbon solution of the appropriate amidine.

When x=0, n=1, one E is NR and the other E is 0 in the formula (I), exemplary organosilane precursors are mono(amidate)carbosilanes R′₃Si—CH₂(R¹N—(CR²)—O) and have the following structural formula:

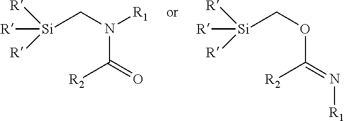

wherein R¹ and R² may each independently be H, a C₁ to C₆ alkyl group, or a C₃-C₂₀ aryl or heterocycle group. R¹ and R² may be joined to form cyclic chains. R′ is independently selected from the group of H, a C to C₆ alkyl group, a C₃-C₂₀ aryl, heterocycle group, C₁-C₆ alkoxy group or C₁-C₆ alkylamino.

Exemplary Mono(Amidate)Carbosilanes Include:

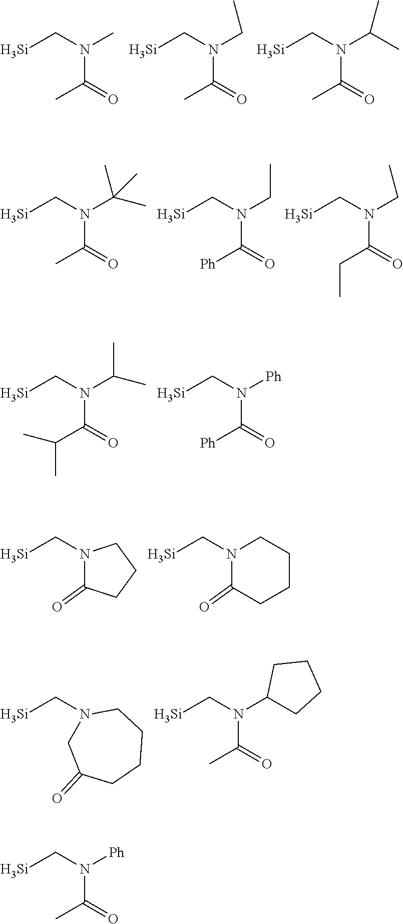

The disclosed R′₃Si—CH₂(R¹N—(CR²)—O) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN(CR)O] under atmosphere of nitrogen, the outlet of the mixing flask being connected to an oil bubbler to inhibit backflow of air and moisture. A second synthetic route to the disclosed R₃Si—CH₂(R¹N—(CR²)—O) precursors is by combining a hydrocarbon solution of XCH₂SiR′₃ wherein X is Cl, Br, I, or triflate (SO₃CF₃), with a neat or hydrocarbon solution of the protonated ligand (RN—(CR)═O) performed under an inert atmosphere. Alternatively, the disclosed R′₃Si—CH₂(R¹N—(CR²)—O) precursors may be synthesized by reaction of XCH₂—SiX₃ wherein X is Cl, Br, I, or triflate (SO₃CF₃) with one equivalent of the ligand compound Li[RN(CR)O] or two equivalents of the ligand compound H[RN(CR)O] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)—O] all of the starting materials are commercially available. The ligand compound may be synthesized by combining a hydrocarbon solution of metalorganic salt (i.e., alkyl lithium) to a hydrocarbon solution of the appropriate amide.

When x=0, n=1, one E is NR and one E is S contain both thioamidate and hydride functionalities in the formula (I), exemplary organosilane precursors are mono(thioamidate)carbosilanes R′₃Si—CH₂(R²N—(CR¹)═S) and have the following structural formula:

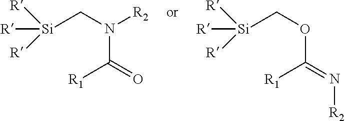

wherein R¹ and R² may each independently be H, a C₁ to C₆ alkyl group, or a C₃-C₂₀ aryl or heterocycle group. R¹ and R² may be joined to form cyclic chains. FR′ is independently selected from the group of H, a C to C₆ alkyl group, a C₃-C₂₀ aryl, heterocycle group, C₁-C₆ alkoxy group or C₁-C₆ alkylamino.

Exemplary Mono(Thioamidate)Carbosilanes Include:

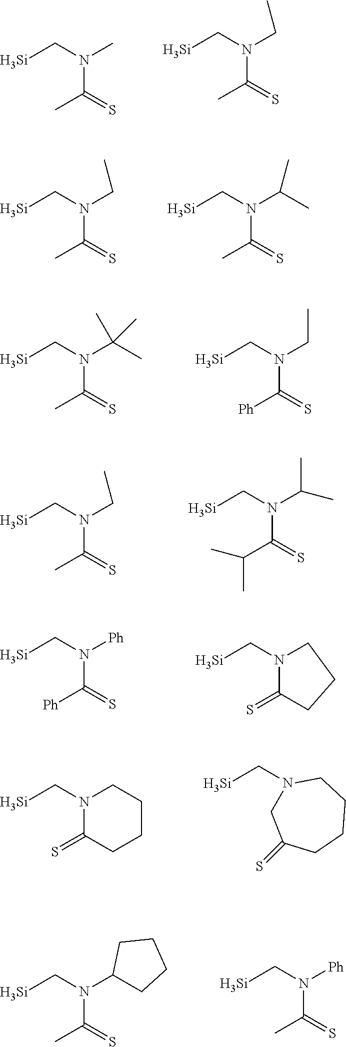

The disclosed R′₃Si—CH₂(R²N—(CR¹)═S) precursors may be synthesized by combining a hydrocarbon solution of XCH₂SiR′₃, wherein X is Cl, Sr, I, or triflate (SO₃CF₃), with a neat or hydrocarbon solution of the ligand compound, such as Li[RN—(CR)═S] under atmosphere of nitrogen, the outlet of the mixing flask being connected to an oil bubbler to inhibit backflow of air and moisture. A second synthetic route to the disclosed R′₃Si—CH₂(R²N—(CR¹)═S) precursors is by combining a hydrocarbon solution of XCH₂SiR′₃, wherein X is Cl, Br, I, or triflate (SO₃CF₃), with a neat or hydrocarbon solution of the protonated ligand H[RN(CR)═S] performed under an inert atmosphere. Alternatively, the disclosed R′₃Si—CH₂(R²N—(CR¹)═S) precursors may be synthesized by reaction of XCH₂—SiX₃ wherein X is Cl, Br, I, or triflate (SO₃CF₃) with one equivalent of the ligand compound Li[RN—(CR)═S] or two equivalents of the ligand compound H[RN—(CR)═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)═S] all of the starting materials are commercially available. The ligand compound may be synthesized by combining a hydrocarbon solution of metalorganic salt (i.e., alkyl lithium) to a hydrocarbon solution of the appropriate thioamide.

When x=0, n=1, and each E=O contain both acetate and hydride functionalities in the formula (I), exemplary organosilane precursors are mono(acetate)carbosilanes SiR′₃—CH₂(O—(CR)═O) and have the following structural formula:

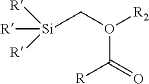

wherein R be H, a C₁ to C₆ alkyl group, or a C₃-C₂₀ aryl or heterocycle group. R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(Acetate)Carbosilanes Include;

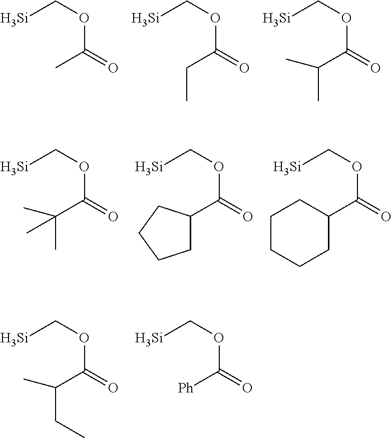

The disclosed SiR′₃—CH₂(O—(CR)═O) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[O—(CR)═O] under atmosphere of nitrogen, the outlet of the mixing flask being connected to an oil bubbler to inhibit backflow of air and moisture. A second synthetic route to the disclosed SiR′₃—CH₂(O—(CR)═O) precursors is by combining a hydrocarbon solution of XCH₂SiR′₃, wherein X is Cl, Br, I, or triflate (SO₃CF₃), with a neat or hydrocarbon solution of the protonated ligand (O—(CR)═O) performed under an inert atmosphere. Alternatively, the disclosed SiR′₃—CH₂(O—(CR)═O) precursors may be synthesized by reaction of XCH₂—SiX₃ wherein X is Cl, Br, I, or triflate (SO₃CF₃) with one equivalent of the ligand compound Li[O—(CR)═O] or two equivalents of the ligand compound H[O—(CR)═O] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[O—(CR)═O] all of the starting materials are commercially available. The ligand compound may be synthesized by combining a hydrocarbon solution of metalorganic salt (i.e., alkyl lithium) to a hydrocarbon solution of the appropriate carboxylic acid or carbon dioxide.

When x=0, n=1, one E is 0 and one E is S contain both thioacetate and hydride functionalities in the formula (I), exemplary organosilane precursors are mono(thioacetate)carbosilanes SiR′₃—CH₂(O—(CR)═S) and have the following structural formula:

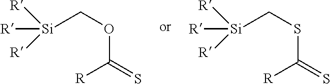

wherein R be H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(Thioacetate)Carbosilanes Include:

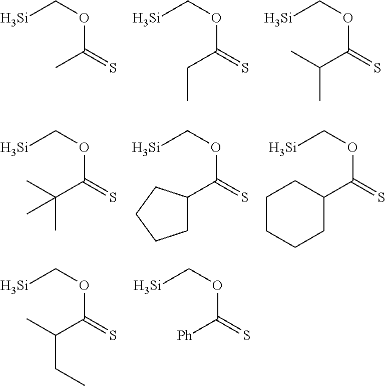

The disclosed SiR′₃—CH₂(O—(CR)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[O—(CR)═S] under atmosphere of nitrogen, the outlet of the mixing flask being connected to an oil bubbler to inhibit backflow of air and moisture. A second synthetic route to the disclosed SiR′₃—CH₂(O—(CR)═S) precursors is by combining a hydrocarbon solution of XCH₂SiR′₃, wherein X is Cl, Br, I, or triflate (SO₃CF₃), with a neat or hydrocarbon solution of the protonated ligand (O—(CR)═S) performed under an inert atmosphere. Alternatively, the disclosed SiR′₃—CH₂(O—(CR)═S) precursors may be synthesized by reaction of XCH₂—SiX₃ wherein X is Cl, Br, I, or triflate (SO₃CF₃) with one equivalent of the ligand compound Li[O—(CR)═S] or two equivalents of the ligand compound H[O—(CR)═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[O—(CR)═S] all of the starting materials are commercially available. The ligand compound may be synthesized by combining a hydrocarbon solution of metalorganic salt (i.e., alkyl lithium) to a hydrocarbon solution of the appropriate thiocarboxylic acid or carbonyl sulfide.

When x=0, n=1, and each E=S contain both dithiocarboxylate and hydride functionalities in the formula (I), exemplary organosilane precursors are mono(dithioacetate)carbosilanes SiR′₃—CH₂(S—(CR)═S) and have the following structural formula:

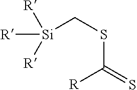

wherein R be H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(Dithioacetate)Carbosilanes Include:

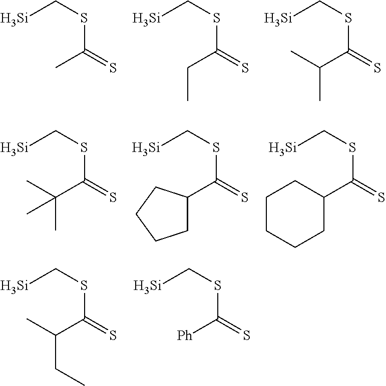

The disclosed SiR′₃—CH₂(S—(CR)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[S—(CR)═S] under atmosphere of nitrogen, the outlet of the mixing flask being connected to an oil bubbler to inhibit backflow of air and moisture. A second synthetic route to the disclosed SiR′₃—CH₂(S—(CR)═S) precursors is by combining a hydrocarbon solution of XCH₂SiR′₃, wherein X is Cl, Br, I, or triflate (SO₃CF₃), with a neat or hydrocarbon solution of the protonated ligand (S—(CR)═S) performed under an inert atmosphere. Alternatively, the disclosed SiR′₃—CH₂(S—(CR)═S) precursors may be synthesized by reaction of XCH₂—SiX₃ wherein X is Cl, Br, I, or triflate (SO₃CF₃) with one equivalent of the ligand compound Li[S—(CR)═S] or two equivalents of the ligand compound H[S—(CR)═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[S—(CR)═S] all of the starting materials are commercially available. The ligand compound may be synthesized by combining a hydrocarbon solution of metalorganic salt (i.e., alkyl lithium) to a hydrocarbon solution of the appropriate dithiocarboxylic acid or carbon disulfide.

When x=0, n=3, and each E=NR contain both β-diketiminate and hydride functionalities in the formula (I), exemplary organosilane precursors are mono(β-diketiminate)carbosilanes SiR′₃—CH₂(R¹N—(CR²)—(CR³)—(CR⁴)—NR⁵ and have the following structural formula:

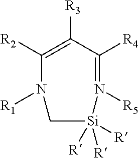

(tetracoordinated Si),

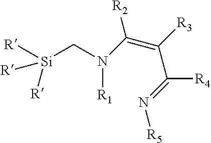

(pentacoordinated Si), wherein R¹, R², R³, R⁴ and R⁵ may each independently be H, a C₁ to C₆ alkyl group, or a C₃-C₂₀ aryl or heterocycle group. R¹ and R² and/or R² and R³ and/or R³ and R⁴ and/or R⁴ and R⁵ may be joined to form cyclic chains; R′ is independently selected from the group of H, a C₁ to C₆ alkyl group, a C₃-C₂₀ aryl, heterocycle group, C₁-C₆; alkoxy group or C₁-C₆ alkylamino.

### Exemplary Mono(β-Diketiminate)Carbosilanes Include:

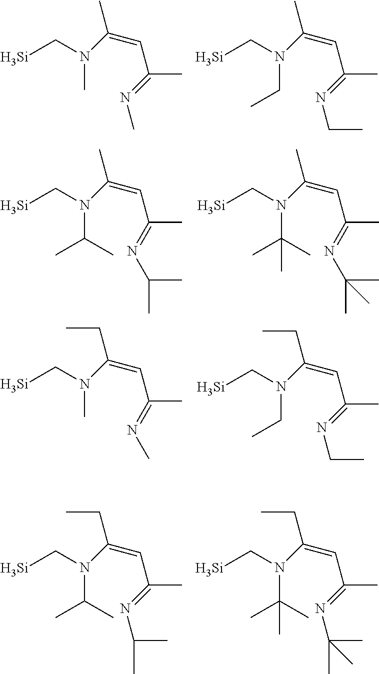

The disclosed SiR′₃—CH₂(R¹N—(CR²)—(CR³)—(CR⁴)—NR⁵ precursors may be synthesized by combining a hydrocarbon solution of XCH₂SiR′₃ wherein X is Cl, Br, I, or triflate (SO₃CF₃), with a neat or hydrocarbon solution of the ligand compound, such as Li[RN—(CR)₃—NR] under atmosphere of nitrogen, the outlet of the mixing flask being connected to an oil bubbler to inhibit backflow of air and moisture. A second synthetic route to the disclosed SiR′₃—CH₂(R¹N—(CR²)—(CR³)—(CR⁴)—NR⁵ precursors is by combining a hydrocarbon solution of XCH₂SiR′₃, wherein X is Cl, Br, I, or triflate (SO₃CF₃), with a neat or hydrocarbon solution of the protonated ligand (RN—(CR)₃—NR) performed under an inert atmosphere. Alternatively, the disclosed SiR′₃—CH₂(R¹N—(CR²)—(CR³)—(CR⁴)—NR⁵ precursors may be synthesized by reaction of XCH₂—SiX₃ wherein X is Cl, Br, I, or triflate (SO₃CF₃) with one equivalent of the ligand compound Li[RN—(CR)₃—NR] or two equivalents of the ligand compound H[RN—(CR)₃—NR] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)₃—NR] all of the starting materials are commercially available. The ligand compound may be synthesized by combining a hydrocarbon solution of metalorganic salt (i.e., alkyl lithium) to a hydrocarbon solution of the appropriate β-diketimine.

When x=0, n=3, one E is NR and one E is 0 contain both β-ketiminate and hydride functionalities in the formula (I), exemplary organosilane precursors mono(β-ketiminate)carbosilanes SiR′₃—CH₂(R¹N—(CR²)—(CR³)—(CR⁴)═O) are and have the following structural formula:

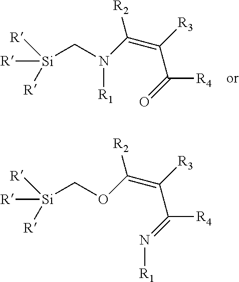

wherein R¹, R², R³ and R⁴ may each independently be H, a C₁ to C₆ alkyl group, or a C₃-C₂₀ aryl or heterocycle group. R¹ and R² and/or R² and R³ and/or R³ and R⁴ may be joined to form cyclic chains; R′ is independently selected from the group of H, a C₁ to Cₑ alkyl group, a C₃-C₂₀ aryl, heterocycle group, C₁-C₆ alkoxy group or C₁-C₈ alkylamino.

Exemplary Mono(3-Ketiminate)Carbosilanes Include:

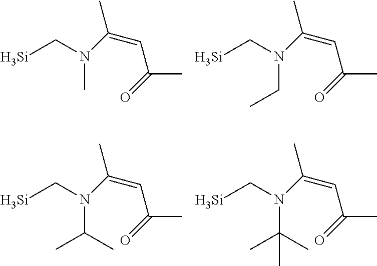

The disclosed SiR′₃—CH₂(R¹N—(CR²)—(CR³)—(CR⁴)═O) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN—(CR)₃═O] under atmosphere of nitrogen, the outlet of the mixing flask being connected to an oil bubbler to inhibit backflow of air and moisture. A second synthetic route to the disclosed SiR′₃—CH₂(R¹N—(CR²)—(CR³)—(CR⁴)═O) precursors is by combining a hydrocarbon solution of XCH₂SiR′₃, wherein X is Cl, Br, I, or triflate (SO₃CF₃), with a neat or hydrocarbon solution of the protonated ligand (RN—(CR)₃═O) performed under an inert atmosphere. Alternatively, the disclosed SiR′₃—CH₂(R¹N—(CR²)—(CR³)—(CR⁴)═O) precursors may be synthesized by reaction of XCH₂—SiX₃ wherein X is Cl, Sr, I, or triflate (SO₃CF₃) with one equivalent of the ligand compound Li[RN—(CR)₃═O] or two equivalents of the ligand compound H[RN—(CR)₃═O] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)₃═O] all of the starting materials are commercially available. The ligand compound may be synthesized by combining a hydrocarbon solution of metalorganic salt (i.e., alkyl lithium) to a hydrocarbon solution of the appropriate β-ketimine.

When x=0, n=3, one E is NR and one E is S contain both β-thioketiminate and hydride functionalities in the formula (I), exemplary organosilane precursors are mono(β-thioketiminate)carbosilanes SiR′₃—CH₂(R¹N—(CR²)—(CR³)—(CR⁴)═S) and have the following structural formula:

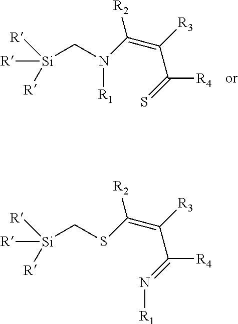

wherein R¹, R², R³ and R⁴ may each independently be H, a C₁ to C₆ alkyl group, or a C₃-C₂₀ aryl or heterocycle group. R¹ and R² and/or R² and R³ and/or R³ and R⁴ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(3-Thioketiminate)Carbosilanes Include:

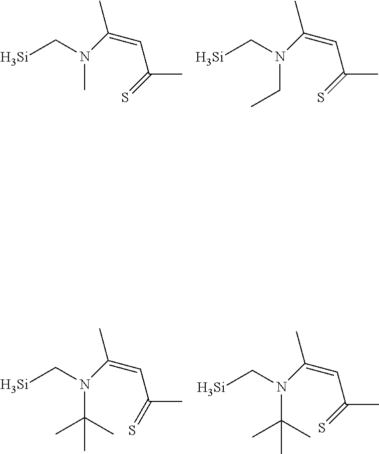

The disclosed SiR′₃—CH₂(R¹N—(CR²)—(CR³)—(CR⁴)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN—(CR)₃═S] under atmosphere of nitrogen, the outlet of the mixing flask being connected to an oil bubbler to inhibit backflow of air and moisture. A second synthetic route to the disclosed SiR′₃—CH₂(R¹N—(CR²)—(CR³)—(CR⁴)═S) precursors is by combining a hydrocarbon solution of XCH₂SiR′₃, wherein X is Cl, Br, I, or triflate (SO₃CF₃), with a neat or hydrocarbon solution of the protonated ligand (RN—(CR)₃═S) performed under an inert atmosphere. Alternatively, the disclosed SiR′₃—CH₂(R¹N—(CR²)—(CR³)—(CR⁴)═S) precursors may be synthesized by reaction of XCH₂—SiX₃ wherein X is Cl, Br, I, or triflate (SO₃CF₃) with one equivalent of the ligand compound Li[RN—(CR)₃═S] two equivalents of the ligand compound H[RN—(CR)₃═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)₃═S] all of the starting materials are commercially available. The ligand compound may be synthesized by thiolation of the corresponding β-ketimine using H₂S/I₂ (see Benvenuti et al, Applied Catalysis A, 199, 2000, 123-132) followed by combining a hydrocarbon solution of metalorganic salt (i.e., alkyl lithium) to a hydrocarbon solution of the resultant 3-thioketimine.

Mien x=0, n=3, and each E is 0 contain both diketonate and hydride functionalities in the formula (I), exemplary organosilane precursors are mono(β-diketonate)carbosilanes SiR′₃—CH₂(O—(CR¹)—(CR²)—(CR³)═O) and have the following structural formula:

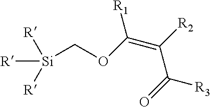

wherein R¹, R² and R³ may each independently be H, a C₁ to C₆ alkyl group, or a C₃-C₂₀ aryl or heterocycle group. R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(β-Diketonate)Carbosilanes Include:

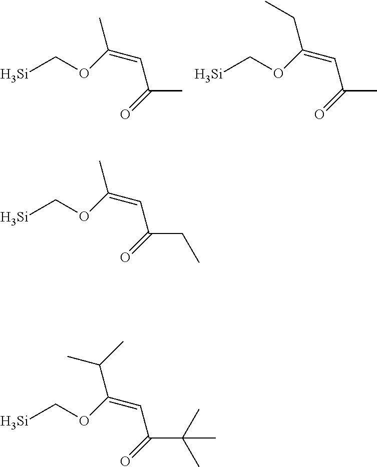

The disclosed SiR′₃—CH₂(O—(CR¹)—(CR²)—(CR³)═O) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[O—(CR)₃═O] under atmosphere of nitrogen, the outlet of the mixing flask being connected to an oil bubbler to inhibit backflow of air and moisture. A second synthetic route to the disclosed SiR′₃—CH₂(O—(CR¹)—(CR²)—(CR³)═O) precursors is by combining a hydrocarbon solution of XCH₂SiR′₃, wherein X is Cl, Br, I, or triflate (SO₃CF₃), with a neat or hydrocarbon solution of the protonated ligand (O—(CR)₃═O) performed under an inert atmosphere. Alternatively, the disclosed SiR′₃—CH₂(O—(CR′)—(CR²)—(CR³)═O) precursors may be synthesized by reaction of XCH₂—SiX₃ wherein X is Cl, Br, I, or triflate (SO₃CF₃) with one equivalent of the ligand compound Li[O—(CR)₃═O] two equivalents of the ligand compound H[O—(CR)₃═O] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[O—(CR)₃═O] all of the starting materials are commercially available. The ligand compound may be synthesized by combining a hydrocarbon solution of metalorganic salt (i.e., alkyl lithium) to a hydrocarbon solution of the appropriate β-diketone.

When x=0, n=3, one E is 0 and one E is S contain both β-thioketonate and hydride functionalities in the formula (I), exemplary organosilane precursors are mono(β-thioketonate)carbosilanes SiR′₃—CH₂(O—(CR¹)—(CR²)—(CR³)═S) and have the following structural formula:

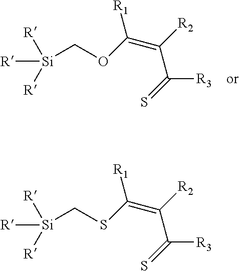

wherein R¹, R² and R³ may each independently be H, a C₁ to C₆ alkyl group, or a C₃-C₂₀ aryl or heterocycle group. R¹ and R² and/or R² and R³ may be joined to form cyclic chains: R′ is independently selected from the group of H, a C₁ to Cc alkyl group, a C₃-C₂₀ aryl, heterocycle group, C₁-C₆ alkoxy group or C₁-C₆ alkylamino.

Exemplary Mono(3-Thioketonate)Carbosilanes Include:

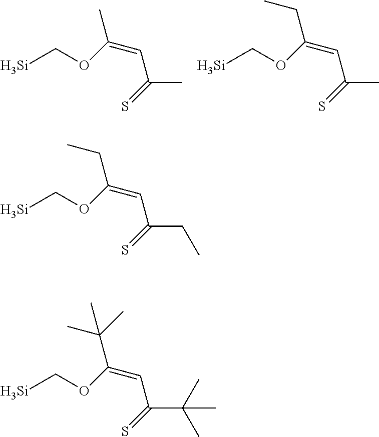

The disclosed SiR′₃—CH₂(O—(CR¹)—(CR²)—(CR³)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[O—(CR)₃═S] under atmosphere of nitrogen, the outlet of the mixing flask being connected to an oil bubbler to inhibit backflow of air and moisture. A second synthetic route to the disclosed SiR′₃—CH₂(0-(CR¹)—(CR²)—(CR³)═S) precursors is by combining a hydrocarbon solution of XCH₂SiR′₃, wherein X is Cl, Br, I, or triflate (SO₃CF₃), with a neat or hydrocarbon solution of the protonated ligand (O—(CR)₃═S) performed under an inert atmosphere. Alternatively, the disclosed SiR′₃—CH₂(O—(CR¹)—(CR²)—(CR³)═S) precursors may be synthesized by reaction of XCH₂—SiX₃ wherein X is Cl, Br, I, or triflate (SO₃CF₃) with one equivalent of the ligand compound Li[O—(CR)₃═S] two equivalents of the ligand compound H[O—(CR)₃═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[O—(CR)₃═S] all of the starting materials are commercially available. The ligand compound may be synthesized by thiolation of the corresponding β-diketone using H₂S/I₂ (see Benvenuti et al, Applied Catalysis A, 199, 2000, 123-132) followed by combining a hydrocarbon solution of metalorganic salt (i.e., alkyl lithium) to a hydrocarbon solution of the resultant β-thioketone.

When x=0, n=3, and each E is S contain both β-dithioketonate and hydride functionalities in the formula (I), exemplary organosilane precursors are mono(dithio-β-diketonate)carbosilanes SiR′₃—CH₂(S—(CR¹)—(CR²)—(CR³)═S) and have the following structural formula:

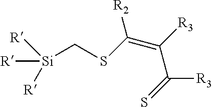

wherein R¹, R² and R³ may each independently be H, a C₁ to C₆ alkyl group, or a C₃-C₂₀ aryl or heterocycle group. R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

Exemplary Mono(Dithio-β-Diketonate)Carbosilanes Include:

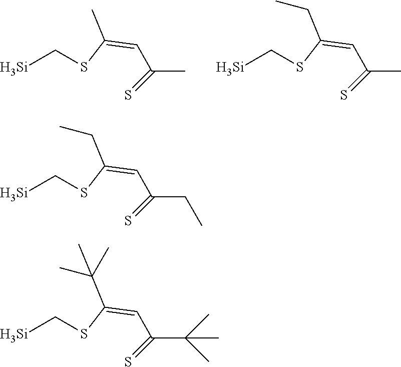

The disclosed SiR′₃—CH₂(S—(CR¹)—(CR²)—(CR³)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[S—(CR)₃═S] under atmosphere of nitrogen, the outlet of the mixing flask being connected to an oil bubbler to inhibit backflow of air and moisture. A second synthetic route to the disclosed SiR′₃—CH₂(S—(CR¹)—(CR²)—(CR³)═S) precursors is by combining a hydrocarbon solution of XCH₂SiR′₃, wherein X is Cl, Br, I, or triflate (SO₃CF₃), with a neat or hydrocarbon solution of the protonated ligand (HS—(CR)₃═S) performed under an inert atmosphere. Alternatively, the disclosed SiR′₃—CH₂(S—(CR¹)—(CR²)—(CR³)═S) precursors may be synthesized by reaction of XCH₂—SiX₃ wherein X is Cl, Br, I, or triflate (SO₃CF₃) with one equivalent of the ligand compound Li[S—(CR)₃═S] two equivalents of the ligand compound H[S—(CR)₃═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[S—(CR)₃═S] all of the starting materials are commercially available. The ligand compound may be synthesized by combining a hydrocarbon solution of metalorganic salt (i.e., alkyl lithium) to a hydrocarbon solution of the appropriate β-dithioketone. The dithioketone may be synthesized by thiolation of the corresponding β-diketone using H₂S/I₂ (see Benvenuti et al, Applied Catalysis A, 199, 2000, 123-132).followed by combining a hydrocarbon solution of metalorganic salt (i.e., alkyl lithium) to a hydrocarbon solution of the resultant β-dithioketone.

When x=1, n=1, and each E=NR contain amidinate functionality in the formula (I), exemplary organosilane precursors are bis(amidinato)carbosilane (SiR′₃—CH₂)₂(R¹N—(CR²)—N) and have the following structural formula:

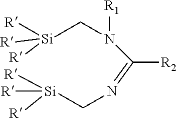

wherein R¹ and R² may each independently be H, a C₁ to C₆ alkyl group, or a C₃-C₂₀ aryl or heterocycle group. R¹ and R² may be joined to form cyclic chains. R′ is independently selected from the group of H, a C₁ to C₆ alkyl group, a 03-C₂₀ aryl, heterocycle group, C₁-C₆ alkoxy group or C₁-C₆ alkylamino,

Exemplary Bis(Amidinato)Carbosilane Include;

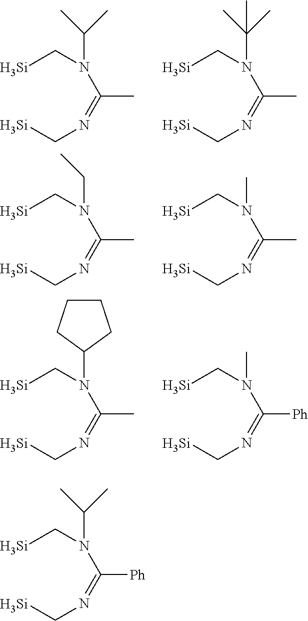

The disclosed (SiR′₃—CH₂)₂(R¹N—(CR²)—N) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN(CR)NH] under atmosphere of nitrogen, the outlet of the mixing flask being connected to an oil bubbler to inhibit backflow of air and moisture. A second synthetic route to the disclosed (SiR′₃—CH₂)₂(R¹N—(CR²)—N) precursors is by combining a hydrocarbon solution of XCH₂SiR′₃, wherein X is Cl, Br, I, or triflate (SO₃CF₃), with a neat or hydrocarbon solution of the protonated ligand (HRN(CR)NH) performed under an inert atmosphere. Alternatively, the disclosed (SiR′₃—CH₂)₂(R¹N—(CR²)—N) precursors may be synthesized by reaction of XCH₂—SiX₃ wherein X is Cl, Br, I, or triflate (SO₃CF₃) with one equivalent of the ligand compound Li[RN(CR)NH] two equivalents of the ligand compound H[RN(CR)NH] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN(CR)NR] all of the starting materials are commercially available. The ligand compound may be synthesized by combining a hydrocarbon solution of metalorganic salt (i.e., alkyl lithium) to a hydrocarbon solution of the appropriate amidine.

When x=1, n=1, one E is NR and the other E is 0 in the formula (I), exemplary organosilane precursors are bis(amidate)carbosilanes (SiR′₃—CH₂)₂(RN—(CR)—O) and have the following structural formula:

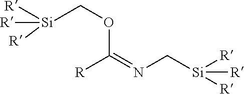

wherein R may each independently be H, a C₁ to C₆ alkyl group, or a C₃-C₂₀ aryl or heterocycle group. R′ is independently selected from the group of H, a C₁ to 06 alkyl group, a C₃-C₂₀ aryl, heterocycle group, C₁-C₆ alkoxy group or C₁-C₆ alkylamino.

Exemplary Bis(Amidate)Carbosilanes Include:

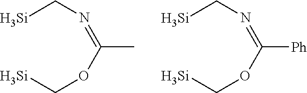

The disclosed (SiR′₃—CH₂)₂(RN—(CR)—O) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN—(CR)—O] under atmosphere of nitrogen, the outlet of the mixing flask being connected to an oil bubbler to inhibit backflow of air and moisture. A second synthetic route to the disclosed (SiR′₃—CH₂)₂(RN—(CR)—O) precursors is by combining a hydrocarbon solution of XCH₂SiR′₃, wherein X is Cl, Br, I, or triflate (SO₃CF₃), with a neat or hydrocarbon solution of the protonated ligand (RN—(CR)═O) performed under an inert atmosphere. Alternatively, the disclosed (SiR′₃—CH₂)₂(RN—(CR)—O) precursors may be synthesized by reaction of XCH₂—SiX₃ wherein X is Cl, Br, I, or triflate (SO₃CF₃) with one equivalent of the ligand compound Li[RN—(CR)—O] two equivalents of the ligand compound H[RN—(CR)—O] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)—O] all of the starting materials are commercially available. The ligand compound may be synthesized by combining a hydrocarbon solution of metalorganic salt (i.e., alkyl lithium) to a hydrocarbon solution of the appropriate amide.

When x=1, n=1, one E is NR and one E is S contain both thioamidate and hydride functionalities in the formula (I), exemplary organosilane precursors are bis(thioamidate)carbosilanes (SiF₃—CH₂)₂(RN—(CR)═S) and have the following structural formula:

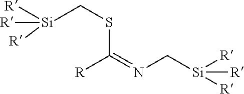

wherein R may each independently be H, a C₁ to C₈ alkyl group, or a C₃-C₂₀ aryl or heterocycle group. R′ is independently selected from the group of H, a C₁ to 06 alkyl group, a C₃-C₂₀ aryl, heterocycle group, C₁-C₆ alkoxy group or C₁-C₆ alkylamino.

Exemplary Bis(Thioamidate)Carbosilanes Include:

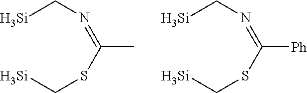

The disclosed (SiR′₃—CH₂)₂(RN—(CR)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN—(CR)═S] under atmosphere of nitrogen, the outlet of the mixing flask being connected to an oil bubbler to inhibit backflow of air and moisture. A second synthetic route to the disclosed (SiR′₃—CH₂)₂(RN—(CR)═S) precursors is by combining a hydrocarbon solution of XCH₂SiR′₃, wherein X is Cl, Br, I, or triflate (SO₃CF₃), with a neat or hydrocarbon solution of the protonated ligand H[RN—(CR)═S] performed under an inert atmosphere. Alternatively, the disclosed (SiR′₃—CH₂)₂(RN—(CR)═S) precursors may be synthesized by reaction of XCH₂—SiX₃ wherein X is Cl, Br, I, or triflate (SO₃CF₃) with one equivalent of the ligand compound Li[RN—(CR)═S] two equivalents of the ligand compound H[RN—(CR)═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)═S] all of the starting materials are commercially available. The ligand compound may be synthesized by combining a hydrocarbon solution of metalorganic salt (i.e., alkyl lithium) to a hydrocarbon solution of the appropriate thioamide.

When x=1, n=3, and each E=NR contain both β-diketiminate and hydride functionalities in the formula (I), exemplary organosilane precursors are bis(β-diketiminate)carbosilanes (SiR′₃—CH₂)₂(R¹N—(CR²)—(CR³)—(CR⁴)—N) and have the following structural formula:

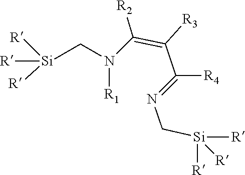

wherein R¹, R², R³ and R⁴ may each independently be H, a C₁ to C₆ alkyl group, or a C₃-C₂₀ aryl or heterocycle group. R¹ and R² and/or R² and R³ and/or R³ and R⁴ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

Exemplary Bis(β-Diketiminate)Carbosilanes Include:

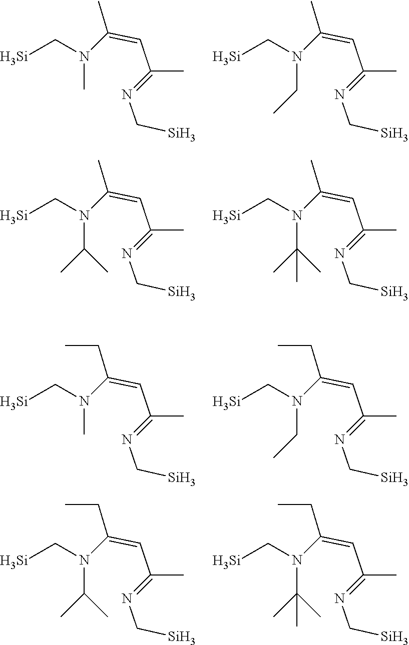

The disclosed (SiR′₃—CH₂)₂(R¹N—(CR²)—(CR³)—(CR″)—N) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[RN—(CR)₃—NH] under atmosphere of nitrogen, the outlet of the mixing flask being connected to an oil bubbler to inhibit backflow of air and moisture. A second synthetic route to the disclosed (SiR′₃—CH₂)₂(R¹N—(CR²)—(CR³)—(CR⁴)—N) precursors is by combining a hydrocarbon solution of XCH₂SiR′₃, wherein X is Cl, Br, I, or triflate (SO₃CF₃), with a neat or hydrocarbon solution of the protonated ligand H[RN—(CR)₃—NH] performed under an inert atmosphere. Alternatively, the disclosed (SiR′₃—CH₂)₂(R¹N—(CR²)—(CR³)—(CR′)—N) precursors may be synthesized by reaction of XCH₂—SiX₃ wherein X is Cl, Br, I, or triflate (SO₃CF₃) with one equivalent of the ligand compound Li[RN—(CR)₃—NH] two equivalents of the ligand compound H[RN—(CR)₃—NH] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)₃—NR] all of the starting materials are commercially available. The ligand compound may be synthesized by combining a hydrocarbon solution of metalorganic salt (i.e., alkyl lithium) to a hydrocarbon solution of the appropriate β-diketimine.

When x=1, n=3, one E is NR and one E is 0 contain both β-ketiminate and hydride functionalities in the formula (I), exemplary organosilane precursors are bis(β-ketiminate)carbosilanes (SiR′₃—CH₂)₂(N—(CR¹)—(CR²)—(CR³)═O) and have the following structural formula:

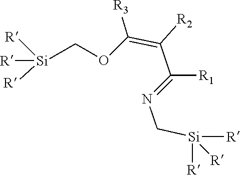

wherein R¹, R² and R³ may each independently be H, a C₁ to C₆ alkyl group, or a C₃-C₂₀ aryl or heterocycle group. R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino,

Exemplary Bis(β-Ketiminate)Carbosilanes Include:

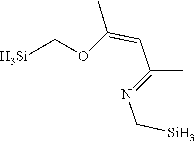

The disclosed (SiR′₃—CH₂)₂(N—(CR¹)—(CR²)—(CR³)═O) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[N—(CR)₃═O] under atmosphere of nitrogen, the outlet of the mixing flask being connected to an oil bubbler to inhibit backflow of air and moisture. A second synthetic route to the disclosed (SiR′₃—CH₂)₂(N—(CR¹)—(CR²)—(CR³)═O) precursors is by combining a hydrocarbon solution of XCH₂SiR′₃, wherein X is Cl, Br, I, or triflate (SO₃CF₃), with a neat or hydrocarbon solution of the protonated ligand H[N—(CR)₃═O] performed under an inert atmosphere. Alternatively, the disclosed (SiR′₃—CH₂)₂(N—(CR¹)—(CR²)—(CR³)═O) precursors may be synthesized by reaction of XCH₂—SiX₃ wherein X is Cl, Br, I, or triflate (SO₃CF₃) with one equivalent of the ligand compound Li[N—(CR)₃═O] two equivalents of the ligand compound H[N—(CR)₃═O] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)₃═O] all of the starting materials are commercially available. The ligand compound may be synthesized by combining a hydrocarbon solution of metalorganic salt (i.e., alkyl lithium) to a hydrocarbon solution of the appropriate β-ketimine.

When x=1, n=3, one E is NR and one E is S contain both β-thioketiminate and hydride functionalities in the formula (I), exemplary organosilane precursors are bis(β-thioketiminate)carbosilanes (SiR′₃—CH₂)₂(N—(CR¹)—(CR²)—(CR³)═S) and have the following structural formula:

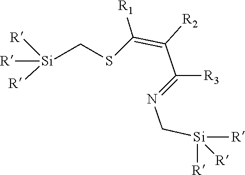

wherein R¹, R² and R³ may each independently be H, a C₁ to C₆ alkyl group, or a C₃-C₂₀ aryl or heterocycle group. R¹ and R² and/or R² and R³ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

Exemplary Bis(β-Thioketiminate)Carbosilanes Include:

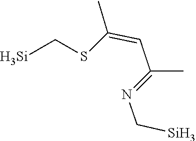

The disclosed (SiR′₃—CH₂)₂(N—(CR¹)—(CR²)—(CR³)═S) precursors may be synthesized by combining a hydrocarbon solution of XCH₂SiR′₃, wherein X is Cl, Br, I, or triflate (SO₃CF₃), with a neat or hydrocarbon solution of the ligand compound, such as Li[N—(CR)₃═S] under atmosphere of nitrogen, the outlet of the mixing flask being connected to an oil bubbler to inhibit backflow of air and moisture. A second synthetic route to the disclosed (SiR′₃—CH₂)₂(N—(CR¹)—(CR²)—(CR³)═S) precursors is by combining a hydrocarbon solution of XCH₂SiR′₃, wherein X is Cl, Br, I, or triflate (SO₃CF₃), with a neat or hydrocarbon solution of the protonated ligand H[N—(CR)₃═S] performed under an inert atmosphere. Alternatively, the disclosed (SiR′₃—CH₂)₂(N—(CR¹)—(CR²)—(CR³)═S) precursors may be synthesized by reaction of XCH₂—SiX₃ wherein X is Cl, Br, I, or triflate (SO₃CF₃) with one equivalent of the ligand compound Li[N—(CR)₃═S] two equivalents of the ligand compound H[N—(CR)₃═S] followed by filtration and subsequent reduction using a selected metal hydride such as LAH (lithium aluminum hydride) for R′=H or amination using a selected amine (R′=dialkylamino group) or alkoxylation with selected alcohol (R′=alkoxy group). In all three synthesis routes, the resulting solution may be stirred at room temperature overnight.

Exemplary hydrocarbon solutions suitable for these synthesis methods include diethyl ether, pentane, hexane, or toluene. The resulting suspension is filtered and the resulting solution distilled to remove solvent. Purification of the resulting liquid or solid is carried out by distillation or sublimation, respectively. Except for the ligand compounds Li[RN—(CR)₃═S] all of the starting materials are commercially available. The ligand compound may be synthesized by thiolation of the corresponding β-ketimine using H₂S/I₂ (see Benvenuti et al, Applied Catalysis A, 199, 2000, 123-132) followed by combining a hydrocarbon solution of metalorganic salt (i.e., alkyl lithium) to a hydrocarbon solution of the resultant β-thioketimine.

In the formula (II), exemplary organosilane precursors are SiH₃—CH₂—N(iPr)₂, SiH₃—CH₂—N(iBu)₂ or the like.

In the formula (III), exemplary organosilane precursors are SiH₃—CH₂—N(iPr)—SiH₃, SiH₃—CH₂—N(iBu)-SiH₃ or the like.

To ensure process reliability, the resulting Si-containing film forming composition may be purified by continuous or fractional batch distillation or sublimation prior to use to a purity ranging from approximately 90% w/w to approximately 100% w/w, preferably ranging from approximately 99% w/w to approximately 100% w/w. The Si-containing film forming compositions may contain any of the following impurities: undesired congeneric species; solvents; chlorinated metal compounds; or other reaction products. Preferably, the total quantity of these impurities is below 0.1% w/w.

The concentration of each of hexane, substituted hexane, pentane, substituted pentane, dimethoxy ether, or anisole in the purified material may range from approximately 0% w/w to approximately 5% w/w, preferably from approximately 0% w/w to approximately 0.1% w/w. Solvents may be used in the composition's synthesis. Separation of the solvents from the composition may be difficult if both have similar boiling points. Cooling the mixture may produce solid precursor in liquid solvent, which may be separated by filtration. Vacuum distillation may also be used, provided the precursor product is not heated above approximately its decomposition point.

In one embodiment, the disclosed Si-containing film forming composition contains less than 5% v/v, preferably less than 1% v/v, more preferably less than 0.1% v/v, and even more preferably less than 0.01% v/v of any of its undesired congeneric species, reactants, or other reaction products. This embodiment may provide better process repeatability. This embodiment may be produced by distillation or sublimation of the Si-containing film forming composition. In an alternate embodiment, the disclosed Si-containing film forming compositions may contain between 5% v/v and 50% v/v of the N, O, S ligands substituted carbosilane precursors, particularly when the mixture provides improved process parameters or isolation of the target precursor is too difficult or expensive. For example, a mixture of reaction products may produce a stable, liquid mixture suitable for spin-on or vapor deposition.

The concentration of trace metals and metalloids in the Si-containing film forming composition may each range from approximately 0 ppb to approximately 100 ppb, and more preferably from approximately 0 ppb to approximately 10 ppb. The concentration of X (wherein X=Cl, Br, I, or F) in the purified Si-containing film forming composition may range from approximately 0 ppm to approximately 100 ppm and more preferably from approximately 0 ppm to approximately 10 ppm.

Also disclosed are methods of using the disclosed organosilane precursors for vapor deposition methods. The disclosed methods provide for the use of the organosilane precursors for deposition of silicon-containing films. The disclosed methods may be useful in the manufacture of semiconductor, photovoltaic, LCD-TFT, or flat panel type devices. The method includes: providing a substrate; providing a vapor including at least one of the disclosed organosilane precursors; and exposing the substrate to the vapor to form a silicon-containing layer on at least one surface of the substrate.

The disclosed organosilane precursors may be used to deposit silicon-containing films using any deposition methods known to those of skill in the art. Examples of suitable deposition methods include without limitation, CVD, ALD, low pressure CVD (LPCVD), pulsed CVD (PCVD), thermal ALD, thermal CVD, plasma enhanced ALD (PEALD), plasma enhanced CVD (PECVD), flowable PECVD, metal organic CVD (MOCVD), spatial ALD, spin-on-deposition (SOD), or combinations thereof. Preferably, the deposition method is ALD, spatial ALD, PEALD or SOD.

The vapor of the organosilane precursor is introduced into a reaction chamber containing at least one substrate. The temperature and the pressure within the reaction chamber and the temperature of the substrate are held at conditions suitable for vapor deposition of at least part of the organosilane precursor onto the substrate. In other words, after introduction of the vaporized precursor into the chamber, conditions within the chamber are such that at least part of the vaporized precursor is deposited onto the substrate to form the silicon-containing film. A reactant may also be used to help in formation of the Si-containing layer.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. AH of these exemplary reaction chambers are capable of serving as an ALD reaction chamber. The reaction chamber may be maintained at a pressure ranging from about 0.5 mTorr to about 20 Torr. In addition, the temperature within the reaction chamber may range from about 20° C. to about 600° C. One of ordinary skill in the art will recognize that the temperature may be optimized through mere experimentation to achieve the desired result.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 20° C. to approximately 600° C. When a plasma deposition process is utilized, the deposition temperature may range from approximately 20° C. to approximately 550° C. Alternatively, when a thermal process is performed, the deposition temperature may range from approximately 300° C. to approximately 600° C.

Alternatively, the substrate may be heated to a sufficient temperature to obtain the desired silicon-containing film at a sufficient growth rate and with desired physical state and composition. A non-limiting exemplary temperature range to which the substrate may be heated includes from 20° C. to 600° C. Preferably, the temperature of the substrate remains less than or equal to 500° C.

The type of substrate upon which the silicon-containing film will be deposited will vary depending on the final use intended. In some embodiments, the substrate may be a patterned photoresist film made of hydrogenated carbon, for example CHₓ, wherein x is greater than zero. In some embodiments, the substrate may be chosen from oxides which are used as dielectric materials in MIM, DRAM, or FeRam technologies (for example, ZrO₂ based materials, HfO₂ based materials, TiO₂ based materials, rare earth oxide based materials, ternary oxide based materials, etc.) or from nitride-based films (for example, TaN) that are used as an oxygen barrier between copper and the low-k layer. Other substrates may be used in the manufacture of semiconductors, photovoltaics, LCD-TFT, or flat panel devices. Examples of such substrates include, but are not limited to, solid substrates such as metal nitride containing substrates (for example, TaN, TiN, WN, TaCN, TiCN, TaSiN, and TiSiN); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances though, the preferred substrate utilized will be selected from hydrogenated carbon, TiN, strontium ruthenium oxide (SRO), Ru, and Si type substrates, such as polysilicon or crystalline silicon substrates.

The substrate may be patterned to include vias or trenches having high aspect ratios. For example, a conformal Si-containing film, such as SiO₂, may be deposited using any ALD technique on a through silicon via (TSV) having an aspect ratio ranging from approximately 20:1 to approximately 200:1.

The Si-containing film forming compositions may be supplied either in neat form or in a blend with a solvent suitable for vapor deposition, such as toluene, ethyl benzene, xylene, mesitylene, decane, dodecane, octane, hexane, pentane, tertiary amines, acetone, tetrahydrofuran, ethanol, ethylmethylketone, 1,4-dioxane, or others. Alternatively, the Si-containing film forming composition may comprise a solvent suitable for casting deposition, such as naphtha, methylisobutylketone (MIRK), n-methylisobutylketone (NMIBK), or combinations thereof. One of ordinary skill in the art will recognize that the casting deposition solution may further comprise pH regulators or surfactants. The disclosed precursors may be present in varying concentrations in the solvent. For example, the resulting concentration of the vapor deposition solution may range from approximately 0.01 M to approximately 2 M. One of ordinary skill in the art will recognize that the molarity of the casting deposition solution is directly proportional to the desired film thickness and may adjust the molarity accordingly.

For vapor deposition, the neat or blended organosilane precursors are introduced into a reactor in vapor form by conventional means, such as tubing and/or flow meters. The precursor in vapor form may be produced by vaporizing the neat or blended precursor solution through a conventional vaporization step such as direct vaporization, distillation, by bubbling, or by using a sublimator known in the art. The neat or blended precursor may be fed in liquid state to a vaporizer where it is vaporized before it is introduced into the reactor.

Alternatively, the neat or blended precursor may be vaporized by passing a carrier gas into a container containing the precursor or by bubbling of the carrier gas into the precursor. The carrier gas may include, but is not limited to, Ar, He, or N₂, and mixtures thereof. Bubbling with a carrier gas may also remove any dissolved oxygen present in the neat or blended precursor solution. The carrier gas and precursor are then introduced into the reactor as a vapor.

If necessary, the container may be heated to a temperature that permits the organosilane precursor to be in its liquid phase and to have a sufficient vapor pressure. The container may be maintained at temperatures in the range of, for example, 0-150° C. Those skilled in the art recognize that the temperature of the container may be adjusted in a known manner to control the amount of organosilane precursor vaporized.

In addition to the disclosed precursor, a co-reactant may also be introduced into the reactor for forming oxygen containing films, such as SiCON and SiO. The co-reactant may be an oxidizing agent such as one of O₂; O₃; H₂O; H₂O₂, N₂O; NO, NO₂, oxygen containing radicals such as [symbol] or O [symbol] ; NO; NO₂; carboxylic acids such as formic acid, acetic acid, propionic acid; radical species of NO, NO₂, or the carboxylic acids; para-formaldehyde; and mixtures thereof. Preferably, the oxidizing agent is selected from the group consisting of O₂, C₃, H₂O, H₂C₂, N₂O, NO, NO₂, oxygen containing radicals thereof such as [symbol] or O [symbol] , and mixtures thereof. Preferably, when an ALD process is performed, the reactant is plasma treated oxygen, ozone, oxygen-containing gas, or combinations thereof. When an oxidizing gas is used; the resulting silicon containing film will also contain oxygen.

Alternatively, the co-reactant may be a reducing agent such as one of H₂, NH₃, (SiH₃)₃N, hydridosilanes (such as SiH₄, Si₂H₆, Si₃H₃, Si₄H₁₀, Si₅H₁₀, Si₆H₁₂), halosilanes including chlorosilanes and chloropolysilanes (such as SiHCl₃, SiH₂Cl₂, SIH₃Cl, Si₂Cl₆, Si₂HCl₅, Si₃Cl₈), alkylsilanes (such as (CH₃)₂SiH₂, (C₂H₅)₂SiH₂, (CH₃)SiH₃, (C₂H₅)SiH₃), hydrazines (such as N2H4, MeHNNH₂, MeHNNHMe), organic amines (such as N(CH₃)H2, N(C₂H₅)H₂, N(CH₃)₂H, N(C₂H₅)₂H, N(CH₃)₃, N(C₂H₅)₃, (SiMe₃)₂NH), pyrazoline, pyridine, B-containing molecules (such as B₂H₆, 9-borabicyclo[3,3,1]none, trimethylboron, triethylboron, borazine), alkyl metals (such as trimethylaluminum, triethylaluminum, dimethylzinc, diethylzinc), radical species thereof, and mixtures thereof. Preferably, the reducing agent is H₂, NH₃, SiH₄, Si₂He, Si₃H₈, SiH₂Me₂, SiH₂Et₂, N(SiH₃)₃, hydrogen radicals thereof, or mixtures thereof. When a reducing agent is used, the resulting silicon containing film may be pure Si.

Additionally, a second precursor may be introduced into the reactor or added to the Si-containing film forming composition. An element of the second precursor is selected from the group consisting of group 2, group 13, group 14, transition metals, lanthanides, and combinations thereof.

The co-reactant may be treated by plasma, in order to decompose the reaction gas into its radical form. N₂ may also be utilized as a reducing agent when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

The disclosed organosilane precursors may also be used with a halosilane or polyhalodisilane, such as hexachlorodisilane pentachlorodisilane, or tetrachlorodisilane, and one or more reactant gases to form SiCN. SiCON, SiN or SiO films.

The disclosed organosilane precursor and one or more co-reactants may be introduced into the reaction chamber simultaneously (chemical vapor deposition), sequentially (atomic layer deposition), or in other combinations. For example, the disclosed organosilane precursor may be introduced in one pulse and two additional metal sources may be introduced together in a separate pulse [modified atomic layer deposition]. Alternatively, the reaction chamber may already contain the reactant prior to introduction of the organosilane precursor. The reactant may be passed through a plasma system localized or remotely from the reaction chamber, and decomposed to radicals. Alternatively, the organosilane precursor may be introduced to the reaction chamber continuously while other metal sources are introduced by pulse (pulsed-chemical vapor deposition). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s. In another alternative, the organosilane precursor and one or more reactants may be simultaneously sprayed from a shower head under which a susceptor holding several wafers is spun (spatial ALD).

In one non-limiting exemplary atomic layer deposition type process, the vapor phase of an organosilane precursor is introduced into the reaction chamber, where it is contacted with a suitable substrate. Excess organosilane precursor may then be removed from the reaction chamber by purging and/or evacuating the reaction chamber. An oxygen source is introduced into the reaction chamber where it reacts with the absorbed organosilane precursor in a self-limiting manner. Any excess oxygen source is removed from the reaction chamber by purging and/or evacuating the reaction chamber. If the desired film is a silicon oxide film, this two-step process may provide the desired film thickness or may be repeated until a film having the necessary thickness has been obtained.

In yet another alternative, a silicon-containing film may be deposited by the flowable PECVD method disclosed in U.S. Pat. App. Pub. No. 2014/0051264 using the disclosed organosilane precursors and a radical nitrogen- or oxygen-containing co-reactant. The radical nitrogen- or oxygen-containing co-reactant, such as NH₃ or H₂O respectively, is generated in a remote plasma system. The radical co-reactant and the vapor phase of the disclosed precursors are introduced into the reaction chamber where they react and deposit the initially flowable film on the substrate. Applicants believe that the nitrogen atom of the disclosed compounds help to further improve the flowability of the deposited film, resulting in films having less voids.

Also disclosed are methods of using the disclosed N, O, S ligands substituted carbosilane precursors in casting deposition methods, such as spin coating (i.e., spin on deposition (SOD)), spray coating, dip coating or slit coating techniques. The disclosed methods provide for the use of the Si-containing film forming composition for deposition of silicon-containing films. The method includes: providing a substrate; applying the liquid form of the disclosed Si-containing film forming composition containing the disclosed organosilane precursor on a substrate; and forming the Si-containing layer on the substrate. As discussed previously, the liquid form of the disclosed Si-containing film forming composition may be a neat solution of the N, O, S ligands substituted carbosilane precursors or a mixture of the precursor with a solvent and optional pH adjusters or surfactants. The liquid form of the disclosed Si-containing film forming composition may be applied directly to the center of the substrate or may be applied to the entire substrate by spraying. When applied directly to the center of the substrate, the substrate may be spun to utilize centrifugal forces to evenly distribute the composition over the substrate. Alternatively, the substrate may be dipped in the Si-containing film forming composition. The resulting film may be dried at an appropriate temperature for a period of time to vaporize any solvent or volatile components of the film. One of ordinary skill in the art would recognize the appropriate temperature selection based on the solvent to be evaporated. During the vaporization process, a mist of water may be sprayed onto the substrate to promote the hydrolysis reaction of the film.

The disclosed N, O, S ligands substituted carbosilane precursors in the Si-containing film forming compositions may prove useful as monomers for the synthesis of silicon containing polymers. The Si-containing film forming compositions may be used to form spin-on dielectric film formulations, for patternable films, or for anti-reflective films. For example, the disclosed Si-containing film forming compositions may be included in a solvent and applied to a substrate to form a film. If necessary, the substrate may be rotated to evenly distribute the Si-containing film forming composition across the substrate. One of ordinary skill in the art will recognize that the viscosity of the Si-containing film forming compositions will contribute as to whether rotation of the substrate is necessary. The resulting film may be heated under an inert gas, such as Argon, Helium, or nitrogen and/or under reduced pressure. Alternatively, electron beams or ultraviolet radiation may be applied to the resulting film. The 8-9 hydrolysable croups of the disclosed N, O, S ligands substituted carbosilane precursors (i.e., the direct Si—Si, Si—N, Si—O, Si—S, or Si—H bonds) may prove useful to increase the connectivity of the polymer obtained.

The silicon-containing films resulting from the processes discussed above may include SiC, SiO₂, SiN, SiON, SiCN, SiCON, SiCOH, pSiCOH. One of ordinary skill in the art will recognize that by judicial selection of the appropriate N, O, S ligands substituted carbosilane precursor and co-reactants, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the silicon-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an 0-containing atmosphere, or combinations thereof. Most preferably, the temperature is 600° C. for less than 3600 seconds under a H-containing atmosphere. The resulting film may contain fewer impurities and therefore may have improved performance characteristics. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the silicon-containing film.

### EXAMPLES

The following non-limiting examples are provided to further illustrate embodiments of the invention. However, the examples are not intended to be all inclusive and are not intended to limit the scope of the inventions described herein.

### Example 1: Synthesis of SiH₃—CH₂—N(iPr)₂

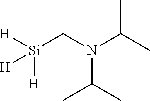

OEt₃SiCH₂Cl+(iPr)₂NH→OEt₃SCH₂N(iPr)₂+LiAlH₄→SiH₃—CH₂—N(iPr)₂ The reaction was done on a 100 g scale of OEt₃SiCH₂Cl and 2 eq. of amine. The starting materials combined in toluene and refluxed for 3 hours. GCMS showed the presence of OEt₃SiCH₂Cl. Further heating for 4 hours showed no change. Worked up and isolated 35.5 g of OEt₃SiCH₂N(iPr)₂ (27% yield, 99% purity). In a 1 L Schlenk flask, equipped with a dropping funnel and under N2, 9.5 g of LiAlH₄ was suspended in THF and cooled with a dry ice bath. OEt₃SiCH₂N(iPr)₂ (81 g) was charged into the dropping funnel then added slowly over 2 hours. The reaction pot was allowed to warm overnight. Volatiles were removed by atmospheric distillation using a 6 inch packed column with helical stainless steel packing. 28 g (67 yield, 99% purity) of SiH₃—CH₂—N(iPr)₂ as a clear colorless liquid was collected. ¹H NMR (C₆D₆): δ 0.89 (d, CH₃), 2.06 (q, CH₂), 2.89 (m, CH), 3.74 (t, SiH₃). ²⁹Si NMR (C₆D₆): δ −61.6.

### Example 2: Synthesis of SiH₃—CH₂—N(iBu)₂

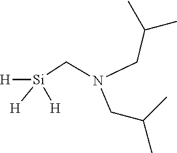

OEt₃SiCH₂Cl+(iBu)₂NH→OEt₃SiCH₂N(iBu)₂+LiAlH₄→SiH₃—CH₂—N(iBu)₂ The reaction was done on a 100 g scale of OEt₃SiCH₂Cl. Two equivalents of the amine, HNiBu₂, was used and the starting materials combined neat and refluxed for 3 hours. The reaction was worked up and 107.7 g of OEt₃SiCH₂N(iBu)₂ (77% yield, 99% purity) isolated. In a 1 L Schlenk flask, equipped with a dropping funnel and under N2, 9.5 g of LiAlH₄ was suspended in THF and cooled with a dry ice bath. OEt₃SiCH₂N(iBu)₂ (100 g) was charged into the dropping funnel then added slowly over 2 hours. The reaction pot was allowed to warm overnight. Material filtered and volatiles were removed by atmospheric distillation using a 6 inch packed column with helical stainless steel packing. 53 g (92 yield, 99% purity) of SiH₃—CH₂—N(iBu)₂ as a clear colorless liquid was collected. 1H NMR (C₆D₆): δ 0.88 (d, CH₃), 1.59 (m, CH), 2.00 (d, CH₂ from iBu group), 2.03 (m, Si—CH₂—N), 3.65 (t, SiH₃). 29Si NMR (C6D6): δ −67.6.

### Example 3: PEALD of SiN Film Using SiH₃—CH₂—N(iBu)₂

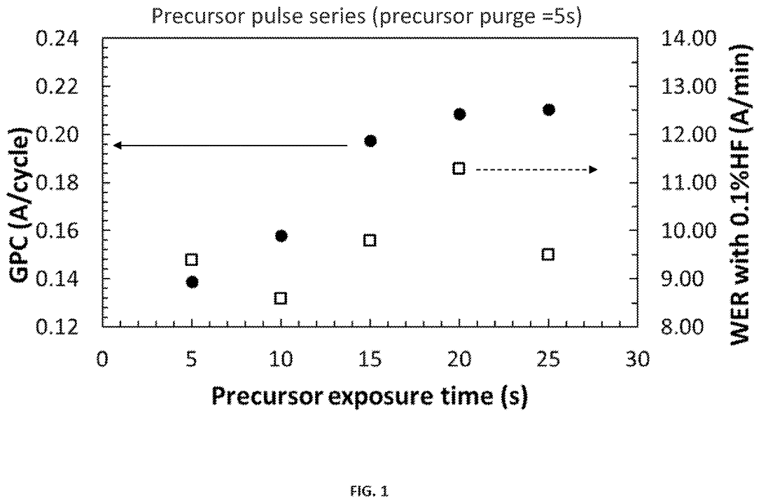

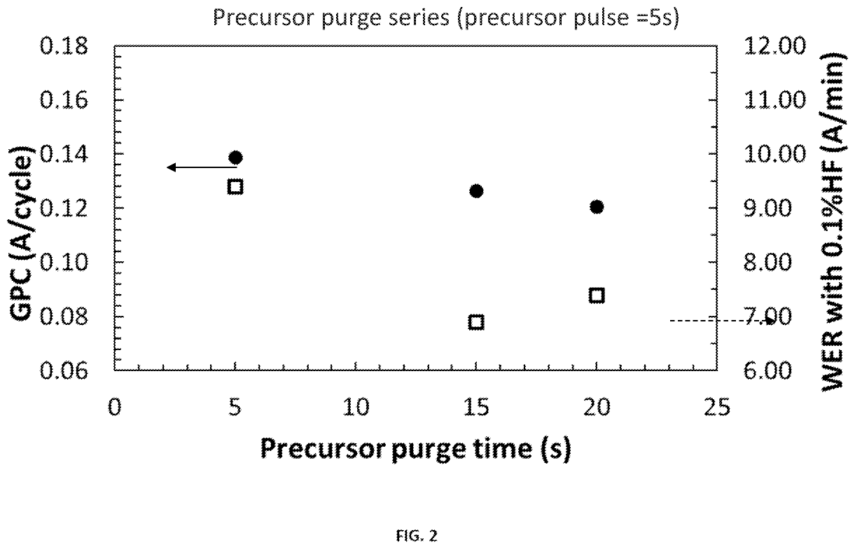

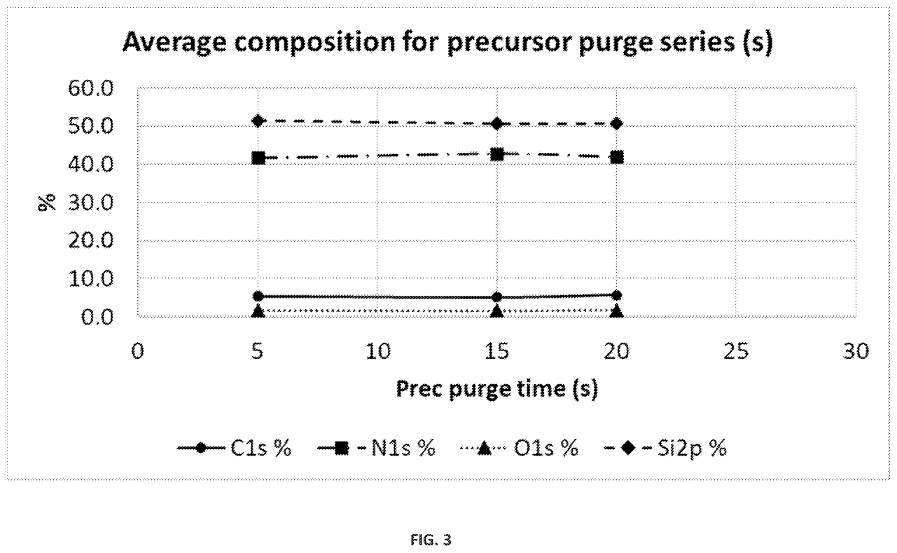

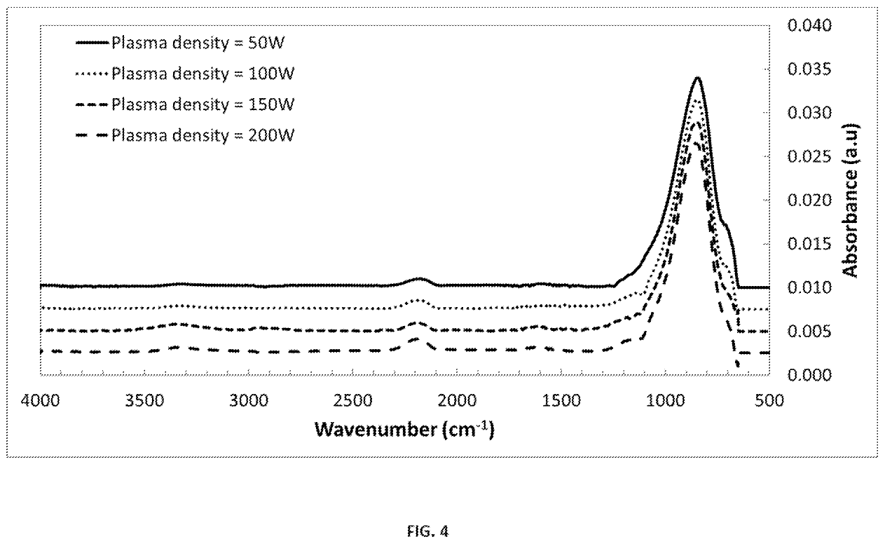

PEALD deposition using precursor SiH₃—CH₂—N(iBu)₂ and co-reactant N₂ was performed on Si substrates. The canister containing SiH₃—CH₂—N(iBu)₂ was maintained at room temperature and 40 Torr. The ALD chamber pressure was set at 1 Torr. The ALD process temperature was set at a temperature of approximately 350° C. A N2 plasma was also employed at 100 Watts. FIG. 1 is a graph of precursor pulse series of Growth Per Cycle (GPC) and Wet Etch Rate (WER), which shows saturation of deposition rate around 15-20 seconds, reaching 0.21 Å/cycle. FIG. 2 is a graph of precursor series showing a slight decrease of deposition rate when the precursor purge is increased from 5 seconds to 20 seconds. For both series, the wet etch rate (WER) has similar tendency. FIG. 3 is the compositional analysis of SiN(C) deposited by SiH₃—CH₂—N(iBu)₂ with N₂ for the precursor purge series, which reveals low oxygen content. Carbon averages approximately 5% in film. FIG. 4 is FTIR (Fourier-transform infrared spectroscopy) spectrum after a plasma power series. We can see the peak for Si—N in the 900 cm⁻¹ region and a small peak at ˜2200 cm⁻¹ for Si—H.

### Prophetic Example 1: Synthesis of H₃SiCH₂—((i-Pr)N(C(CH₃))═N(i-Pr))

One equivalent of (OEt)₃SiCH₂Cl is added, under N₂, to a flask which is equipped with a condenser and addition funnel. The material is heated to approximately 100 to 150° C., ideally 120° C. One to 6 equivalents, ideally 2 equivalents of N,N′-Bis(1-methylethyl)ethanimidamide is added dropwise. The reaction mixture heated for an additional 1 to 5 hours, ideally 3 hours. During the reaction and upon cooling solids are formed. A hydrocarbon solvent is then added, preferably pentane, to form a suspension that is then filtered. The solvent is then removed under vacuum and the crude material purified by distillation. The product (OEt)₃SiCH₂—((i-Pr)N(C(CH₃))═N(i-Pr)) is then added dropwise to a cooled flask under nitrogen that contains a LiAlH₄ (equimolar H in LiAlH₄ to OEt groups in (OEt)₃SiCH₂-((i-Pr)N(C(CH₃))═N(i-Pr)) suspension in an organic solvent such as THF. Upon warming to room temperature the suspension is filtered, the solvent removed under vacuum and the crude material purified, such as by vacuum distillation to obtain the product H₃SiCH₂-((i-Pr)N(C(CH₃))═N(i-Pr)).

### Prophetic Example 2: Synthesis of H₃SiCH₂-((i-Pr)N(C(CH₃))═N(i-Pr))

One equivalent of (OEt)₂SiCH₂Cl is added, under N₂, to a flask containing an organic solvent such as diethylether. A Li-((i-Pr)N(C(CH₃))═N(i-Pr)) suspension in diethyl ether is slowly added to the flask by cannulation. Li-((i-Pr)N(C(CH₃))═N(i-Pr)) is made by addition of methyl lithium to N,N′-diisopropylcarbodimide. The reaction mixture is allowed to react for a period of time, ideally 1 hour. The suspension is then filtered and the solvent removed under vacuum. The solvent is then removed under vacuum and the crude material purified by distillation. The product (OEt)₃SiCH₂-((i-Pr)N(C(CH₃))═N(i-Pr)) is then added dropwise to a cooled flask under nitrogen that contains a LiAlH₄ (equimolar H in LiAlH₄ to OEt groups in (OEt)₃SiCH₂-((i-Pr)N(C(CH₃))═N(i-Pr)) suspension in an organic solvent such as THE. Upon warming to room temperature the suspension is filtered, the solvent removed under vacuum and the crude material purified, such as by vacuum distillation to obtain the product H₃SiCH₂-((i-PON(C(CH₃))═N(i-Pr)).

Although the subject matter described herein may be described in the context of illustrative implementations to process one or more computing application features/operations for a computing application having user-interactive components the subject matter is not limited to these particular embodiments. Rather, the techniques described herein can be applied to any suitable type of user-interactive component execution management methods, systems, platforms, and/or apparatus.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1. A Si-containing film forming composition comprising an organosilane precursor, the organosilane precursor having the following formula:
(R′₃Si—CH₂)-(E-(CR)ₙ-E)-(CH₂—SiR′₃)ₓ (I)
R′₃Si—CH₂)—NR₂ (II)
(R′₃Si—CH₂)—NR—SiR′ (III)
wherein
x is 0 or 1;
(E-(CR)ₙ-E) is a monoanionic bidentate ligand bonding to the carbon through one or two Es, wherein
n is 1 or 3;
each E is independently chosen from N, NR, O or S; and
R is independently selected from the group consisting of H, a C₁ to C₆ alkyl group, and a C₃-C₂₀ aryl or heterocycle group; and
each R′ is independently selected from the group of H, a C₁ to C₆ alkyl group, a C₃-C₂₀ aryl, heterocycle group, C₁-C₆ alkoxy group or C₁-C₆ alkylamino.

2. The Si-containing film forming composition of claim 1, wherein the organosilane precursor is selected from the group consisting of (R′₃Si—CH₂)—(NR¹—(CR²)—NR³), R′₃Si—CH₂(R¹N—(CR²)—O), R′₃Si—CH₂(R²N—(CR¹)═S), SiR′₃—CH₂(O—(CR)═O), SiR′₃—CH₂(O—(CR)═S), SiR′₃—CH₂(S—(CR)═S), SiR′₃—CH₂(R¹N—(CR²)—(CR³)—(CR⁴)—NR⁵, SiR^{′}₃—CH₂(R¹N—(CR²)—(CR³)—(CR⁴)═O), SiR′₃—CH₂(R¹N—(CR²)—(CR³)—(CR⁴)═S), SiR′₃—CH₂(RN—(CR¹)—(CR²)—(CR³)═O), SiR′₃—CH₂(O—(CR¹)—(CR²)—(CR³)═S), SiR′₃—CH₂(S—(CR¹)—(CR²)—(CR³)═S), (SiR′₃—CH₂)₂(R¹N—(CR²)—N), (SiR′₃—CH₂)₂(RN—(CR)—O), (SiR′₃—CH₂)₂(RN—(CR)═S), (SiR′₃—CH₂)₂(R¹N—(CR²)—(CR³)—(CR⁴)—N), (SiR′₃—CH₂)₂(N—(CR¹)—(CR²)—(CR³)═O), and (SiR′₃—CH₂)₂(N—(CR¹)—(CR²)—(CR³)═S), wherein R¹, R², R³, R⁴ and R⁵ each is independently H, a C₁ to C₆ alkyl group, or a C₃-C₂₀ aryl or heterocycle group; R¹ and R² and/or R² and R³ and/or R³ and R⁴ and/or R⁴ and R⁵ may be joined to form cyclic chains; R′ is independently selected from the group of H, a C₁ to C₆ alkyl group, a C₃-C₂₀ aryl, heterocycle group, C₁-C₆ alkoxy group or C₁-C₆ alkylamino.

3. The Si-containing film forming composition of claim 1, wherein the organosilane precursor is selected from the group consisting of (R′₃Si—CH₂)—(NR¹—(CR²)—NR³), R′₃Si—CH₂(R¹N—(CR²)—O), R′₃Si—CH₂(R²N—(CR¹)═S), SiR′₃—CH₂(O—(CR)═O), SiR′₃—CH₂(O—(CR)═S), SiR′₃—CH₂(S—(CR)═S), SiR′₃—CH₂(R¹N—(CR²)—(CR³)—(CR⁴)—NR⁵, SiR′₃—CH₂(R¹N—(CR²)—(CR³)—(CR⁴)═O), SiR′₃—CH₂(R¹N—(CR²)—(CR³)—(CR⁴)═S), SiR′₃—CH₂(O—(CR¹)—(CR²)—(CR³)═O), SiR′₃—CH₂(R¹N—(CR¹)—(CR²)—(CR³)═S), SiR′₃—CH₂(S—(CR¹)—(CR²)—(CR³)═S), (SiR′₃—CH₂)₂(R¹N—(CR²)—N), (SiR′₃—CH₂)₂(RN—(CR)—O), (SiR′₃—CH₂)₂(RN—(CR)═S), (SiR′₃—CH₂)₂(R¹N—(CR²)—(CR³)—(CR⁴)—N), (SiR′₃—CH₂)₂(N—(CR¹)—(CR²)—(CR³)═O), and (SiR′₃—CH₂)₂(N—(CR¹)—(CR²)—(CR³)═S), wherein R¹, R², R³, R⁴ and R⁵ each is independently H, a C₁ to C₆ alkyl group, or a C₃-C₂₀ aryl or heterocycle group; R′ is independently selected from the group of H, a C₁ to C₆ alkyl group, a C₃-C₂₀ aryl, heterocycle group, C₁-C₆ alkoxy group or C₁-C₆ alkylamino.

4. The Si-containing film forming composition of claim 1, wherein the organosilane precursor is selected from the group consisting of

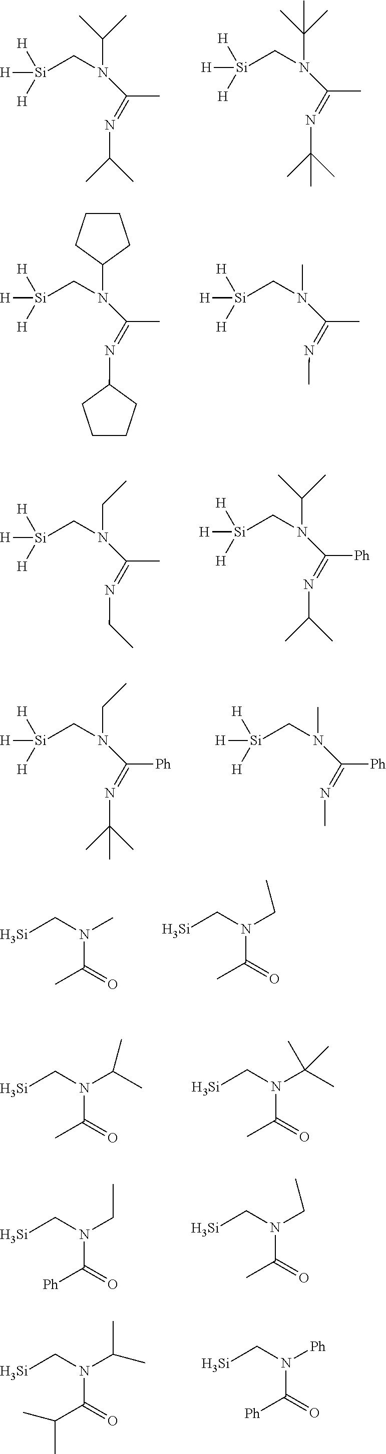

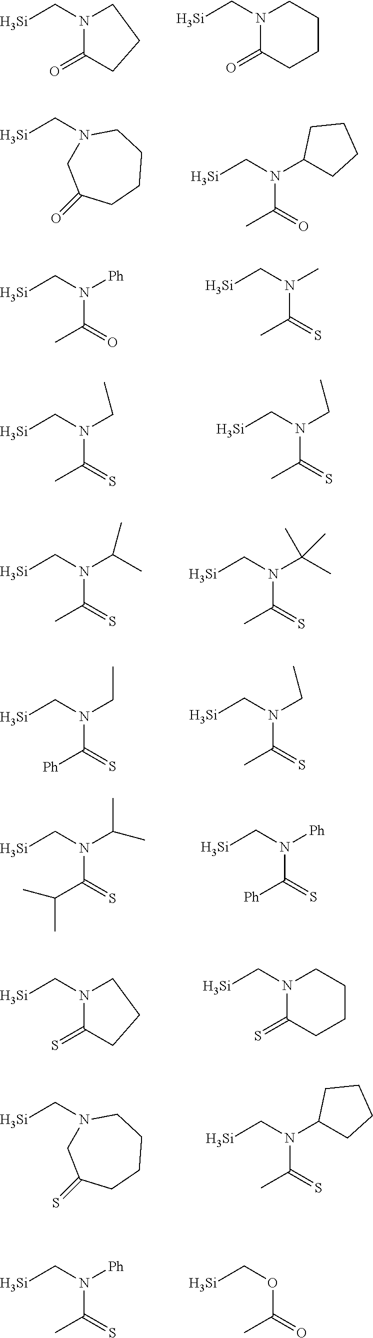

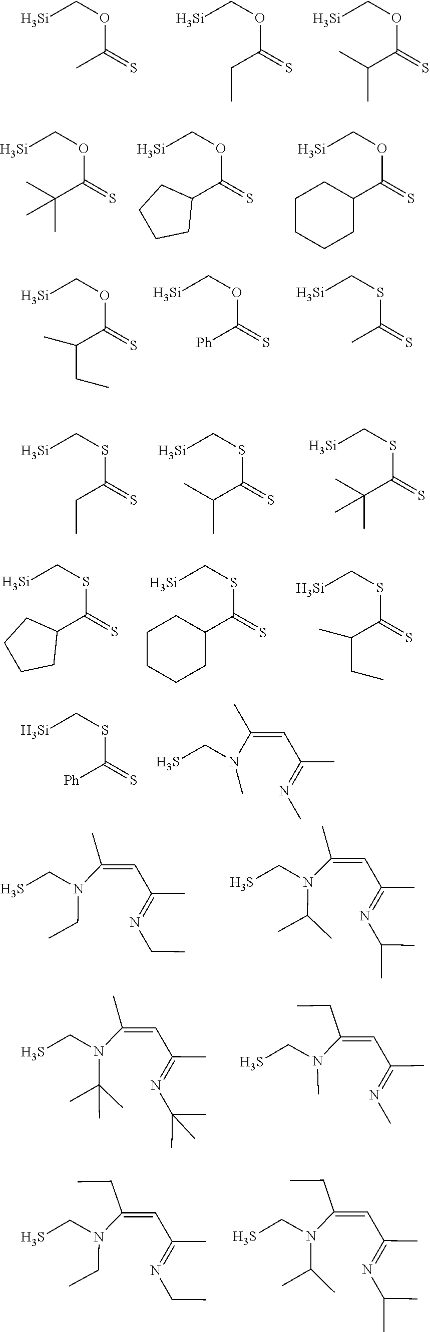

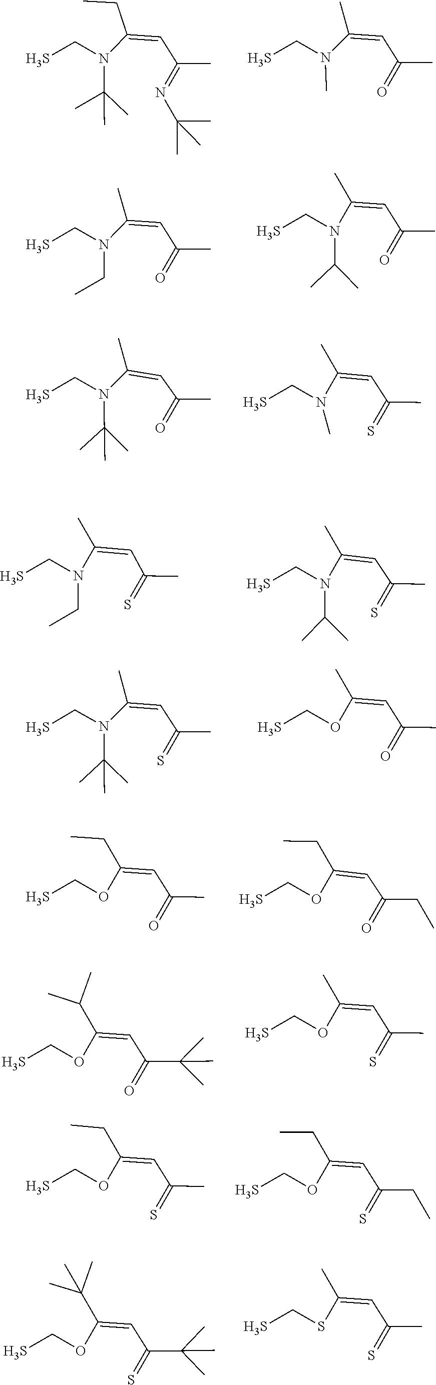

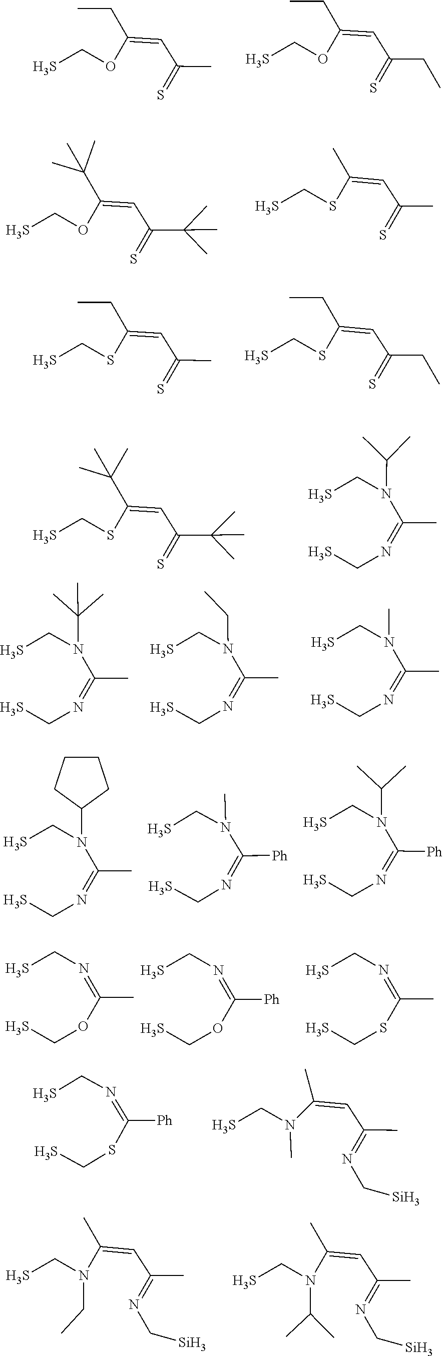

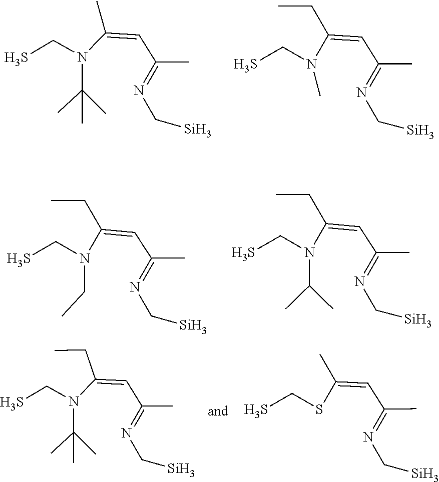

5. The Si-containing film forming composition of claim 1, wherein the organosilane precursor is selected from the group consisting of SiH₃—CH₂—N(iPr)₂ and SiH₃—CH₂—N(iBu)₂.

6. The Si-containing film forming composition of claim 1, wherein the organosilane precursor is H₃SiCH₂—((i-Pr)N(C(CH₃))═N(i-Pr)).

7. The Si-containing film forming composition of claim 1, wherein the organosilane precursor is SiH₃—CH₂—N(iBu)₂.

8. A method of deposition a Si-containing layer on a substrate, the method comprising:
exposing a substrate to a vapor of an Si-containing film forming composition comprising an organosilane precursor having the formula
(R′₃Si—CH₂)-(E-(CR)ₙ-E)-(CH₂—SiR′₃)ₓ (I)
R′₃Si—CH₂)—NR₂ (II)
(R′₃Si—CH₂)—NR—SiR′ (III)
wherein
x is 0 or 1;
(E-(CR)ₙ-E) is a monoanionic bidentate ligand bonding to the carbon through one or two Es, wherein
n is 1 or 3;
each E is independently chosen from N, NR, or S; and
R is independently selected from the group consisting of H, a C₁ to C₆ alkyl group, and a C₃-C₂₀ aryl or heterocycle group; and
each R′ is independently selected from the group of H, a C₁ to C₆ alkyl group, a C₃-C₂₀ aryl, heterocycle group, or C₁-C₆ alkylamino; and
depositing at least part of the organosilane precursor onto the substrate to form a Si-containing layer using a deposition method.

9. The method of claim 8, wherein the deposition method is an ALD or CVD.

10. The method of claim 8, wherein the deposition method is a PEALD or spatial ALD.

11. The method of claim 8, wherein the deposition method is a SOD.

12. The method of claim 8, further comprising the step of adding a co-reactant to the Si-containing film forming composition.

13. The method of claim 12, wherein the co-reactant is selected from the group consisting of O₂, O₃, H₂O, H₂O₂, N₂O, NO, NO₂, a carboxylic acid, plasma treated oxygen-containing gas, radicals thereof, and combinations thereof.

14. The method of claim 12, wherein the co-reactant is O₂ or O₃.

15. The method of claim 12, wherein the co-reactant is selected from the group consisting of H₂, NH₃, (SiH₃)₃N, hydridosilanes (such as SiH₄, Si₂H₆, Si₃H₈, Si₄H₁₀, Si₅H₁₀, Si₆H₁₂), halosilanes including chlorosilanes and chloropolysilanes (such as SiHCl₃, SiH₂Cl₂, SiH₃Cl, Si₂Cl₆, Si₂HCl₅, Si₃Cl₈, Si₂H₂Cl₄, and cyclo-Si₆H₆Cl₆), alkysilanes (such as Me₂SiH₂, Et₂SiH₂, MeSiH₃, EtSiH₃), hydrazines (such as N₂H₄, MeHNNH₂, MeHNNHMe), organic amines (such as NMeH₂, NEtH₂, NMe₂H, NEt₂H, NMe₃, NEt₃, (SiMe₃)₂NH), pyrazoline, pyridine, B-containing molecules (such as B₂H₆, 9-borabicylo[3,3,1]none, trimethylboron, triethylboron, borazine), alkyl metals (such as trimethylaluminum, triethylaluminum, dimethylzinc, diethylzinc), radical species thereof, and mixtures thereof.

16. The method of claim 12, wherein the co-reactant is NH₃.

17. The method of claim 8, wherein the Si-containing layer is a SiN, SiCN, SiO or SiCON layer.

18. The method of claim 8, further comprising adding a second precursor to the Si-containing film forming composition.

19. The method of claim 18, wherein an element of the second precursor is selected from the group consisting of group 2, group 13, group 14, transition metals, lanthanides, and combinations thereof.

20. The method of claim 8, further comprising the step of annealing the Si-containing layer through thermal annealing, furnace-annealing, rapid thermal annealing, UV or e-beam curing, and/or plasma gas exposure.
